(19) United States
(12) Patent Application Publication
(10) Pub. No.: US 2024/0304722 A1
(43) Pub. Date: Sep. 12, 2024

(54) MICROELECTRONIC DEVICES INCLUDING CONTACT STRUCTURES, AND RELATED MEMORY DEVICES, AND ELECTRONIC SYSTEMS

(71) Applicant: Micron Technology, Inc., Boise, ID (US)

(72) Inventors: Darwin A. Clampitt, Wilder, ID (US); Roger W. Lindsay, Boise, ID (US); Martin J. Barclay, Middleton, ID (US)

(21) Appl. No.: 18/424,704

(22) Filed: Jan. 26, 2024

Related U.S. Application Data
(60) Provisional application No. 63/489,631, filed on Mar. 10, 2023.

(51) Int. Cl. H01L 29/78; H10B 41/27; H10B 43/27

(52) U.S. Cl. CPC H01L 29/7827; H10B 41/27; H10B 43/27

(57) ABSTRACT

A microelectronic device comprises a stack structure comprising a vertically alternating sequence of conductive structures and insulative structures arranged in tiers, a staircase structure comprising steps comprising horizontal edges of the tiers, each of the steps comprising multiple tiers, and conductive contact structures vertically extending from a vertically upper surface of the stack structure to the conductive structures of the steps, the conductive structures defining each of the steps individually in contact with a conductive contact structure. Related memory devices and electronic systems are also described.

### CROSS-REFERENCE TO RELATED APPLICATION

This application claims the benefit under 35 U.S.C. § 119(e) of U.S. Provisional Patent Application Ser. No. 63/489,631, filed Mar. 10, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices including staircase structures and conductive contacts in electrical communication with steps of the staircase structures, and to related memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes strings of memory cells vertically extending through one or more stack structures including tiers of conductive material and insulative material. Each string of memory cells may include at least one select device coupled thereto. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive material of the tiers of the stack structure(s) of the memory device and control logic devices (e.g., string drivers) so that the memory cells of the vertical memory array can be uniquely selected for writing, reading, or erasing operations. One method of forming such an electrical connection includes forming so-called “staircase” (or “stair step”) structures at edges (e.g., horizontal ends) of the tiers of the stack structure(s) of the memory device. The staircase structure includes individual “steps” defining contact regions for the conductive material of the tiers, upon which conductive contact structures can be positioned to provide electrical access to the conductive material. In turn, conductive routing structures can be employed to couple the conductive contact structures to the control logic devices. Forming the conductive contact structures includes etching through different vertical heights of an insulative material over the staircase structures. During formation of the conductive contact structures, the conductive contact structures may be formed to a tier vertically underlying a desired tier or neighboring conductive contact structures may inadvertently electrically connect to one another (e.g., short).

### BRIEF DESCRIPTION OF THE DRAWINGS

FIG. 1A through FIG. 1T are simplified partial cross-sectional views (FIG. 1A through FIG. 1E, FIG. 1G through FIG. 1J, FIG. 1L, FIG. 1M, FIG. 1O, FIG. 1P, and FIG. 1R through FIG. 1T) and simplified partial top-down views (FIG. 1F, FIG. 1K, FIG. 1N, and FIG. 1Q) illustrating a method of forming a microelectronic device structure, in accordance with embodiments of the disclosure;

FIG. 2 is a partial cutaway perspective view of a microelectronic device, in accordance with embodiments of the disclosure; and

FIG. 3 is a block diagram of an electronic system, in accordance with embodiments of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for case of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device, such as DRAM memory device), apparatus, memory device, or electronic system, or a complete microelectronic device, apparatus, memory device, or electronic system including conductive contact structures. The structures described below do not form a complete microelectronic device, apparatus, memory device, or electronic system. Only those process acts and structures necessary to understand the embodiments described herein are described in detail below. Additional acts to form a complete microelectronic device, apparatus, memory device, or electronic system from the structures may be performed by conventional techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth.

According to embodiments described herein, a microelectronic device comprises a stack structure comprising a vertically alternating sequence of insulative structures and conductive structures. Slot structures vertically extend through the stack structure and divide the microelectronic device into block structures, each block structure comprising stadium structures comprising staircase structures defining steps at horizontal edges of tiers of alternating conductive structures and insulative structures. Each of the steps is defined by the horizontal edges of the tiers and includes multiple tiers (e.g., more than one tier, such as three tiers). Conductive contact structures are individually in contact with (e.g., electrical communication with) the conductive structures of the steps and vertically extend from an upper surface of the stack structure to the respective conductive structures. The conductive contact structures may be formed in-situ, such as during a replace gate process during which insulative structures and insulative liner materials are replaced with respective conductive structures and the conductive contact structures. In some embodiments, conductive structures of multiple deck structures, each deck structure comprising a vertically alternating sequence of the insulative structures and conductive structures, may be contacted with conductive contact structures in a single replacement process. In some embodiments, the conductive contact structures in contact with different conductive structures of the same step are located at different horizontal distances from a center of the staircase structures. In some embodiments, a vertically uppermost surface defining the steps comprises an insulative structure of the respective step.

Forming the conductive contact structures substantially simultaneously with formation of the conductive structures (e.g., in-situ during formation of the conductive structures) reduces the number of processing acts (e.g., etching acts) to form the conductive contact structures in electrical communication with the conductive structures compared to conventional microelectronic devices. For example, conventional methods of forming microelectronic devices include etching through an insulative material over the conductive structures after forming the conductive structures. Etching through the insulative material to different depths (e.g., due to the different vertical heights of the steps) in conventional methods of forming a microelectronic device may inadvertently result in over etching (e.g., contact punch through) and electrical shorting of vertically neighboring conductive structures to each other. Since the conductive contact structures are formed in contact with the conductive structures of the steps without etching through an insulative material vertically overlying the steps, the conductive structures may not inadvertently electrically short to one another due to so-called “punch through” wherein the insulative material and vertically underlying conductive structures are over etched during conventional methods of forming a microelectronic device structure. In addition, forming the steps to comprise more than one of the tiers facilitates forming the conductive contact structures in contact with the conductive structures, reducing a number of steps and stadium structures formed for a particular number of tiers compared to conventional microelectronic devices.

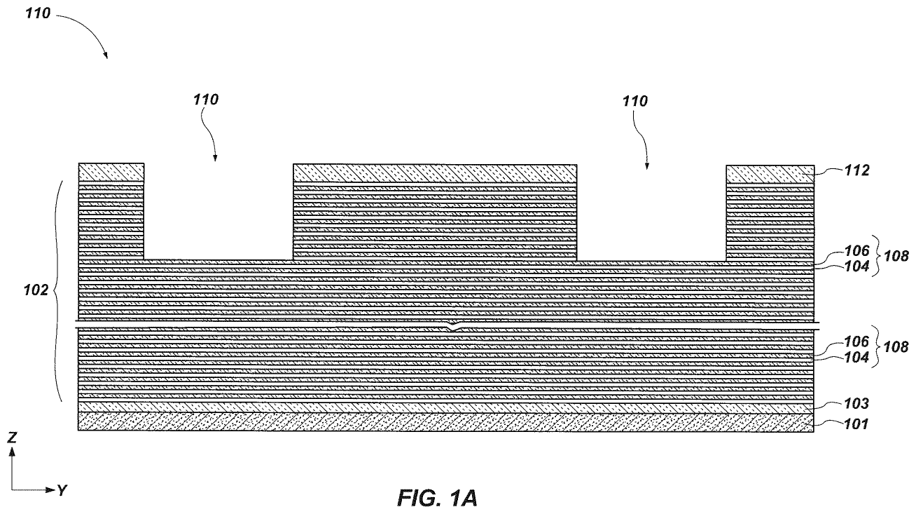

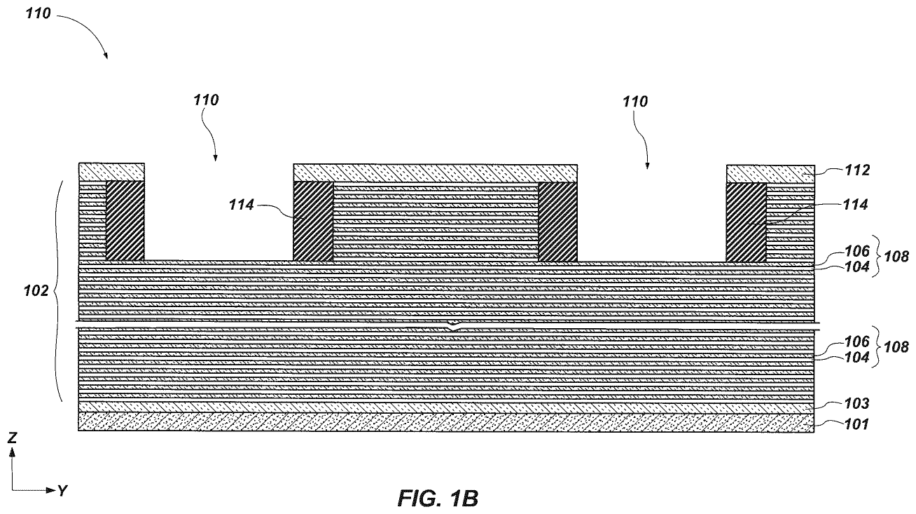

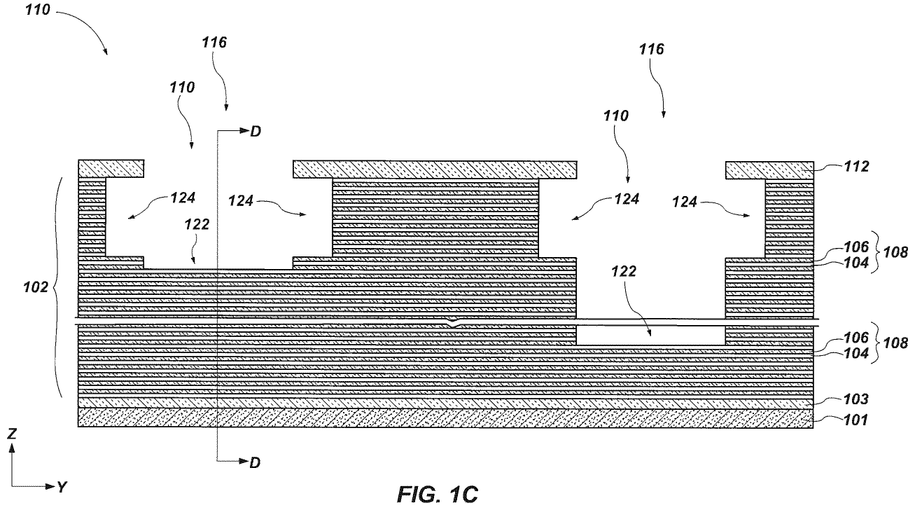

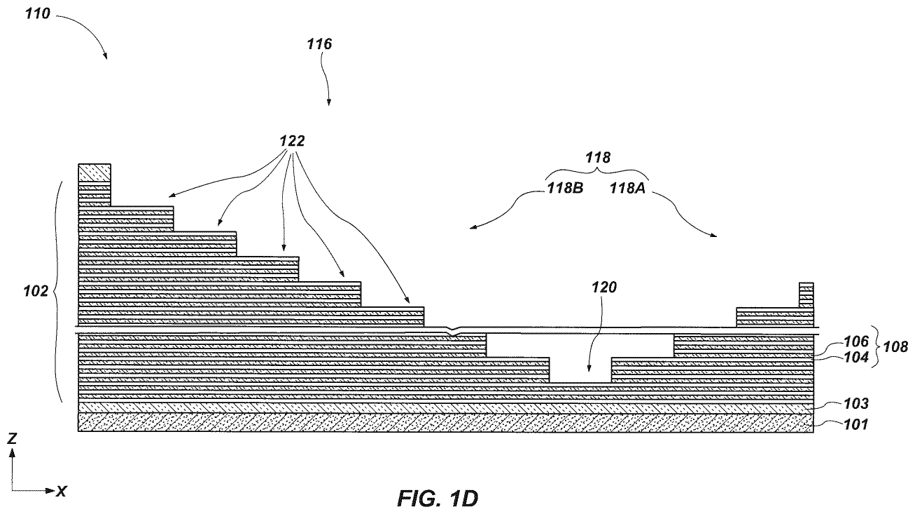

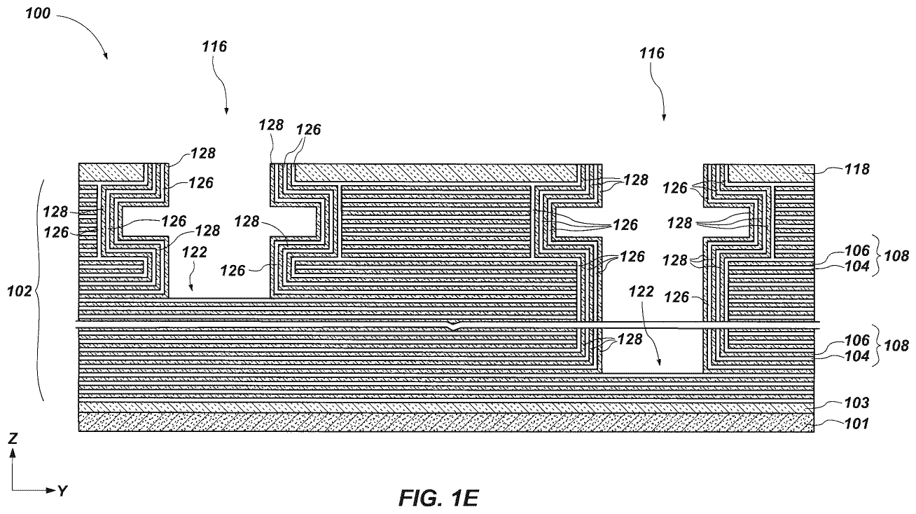

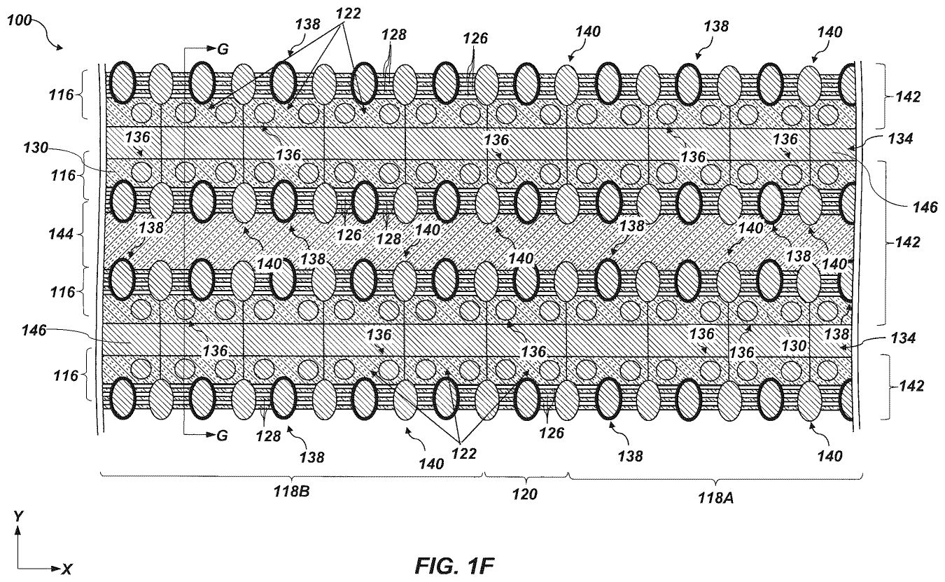

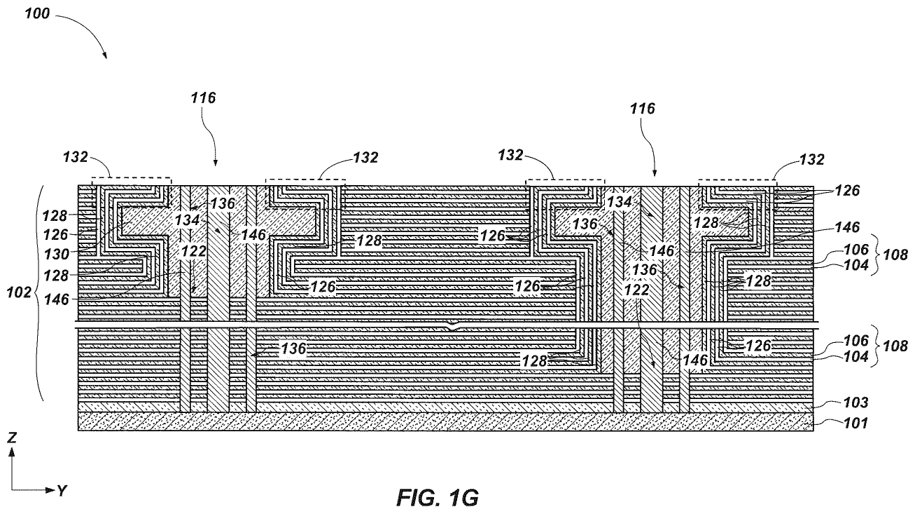

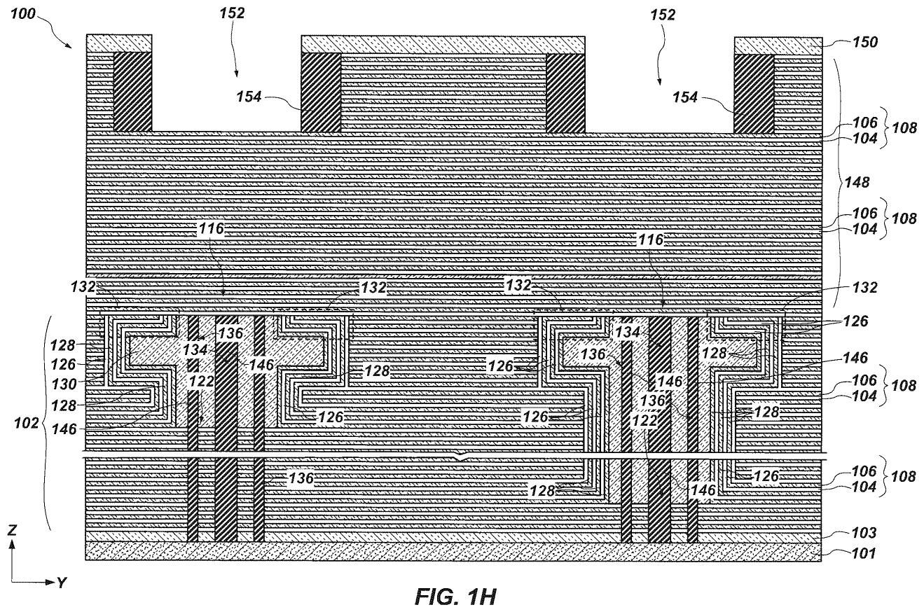

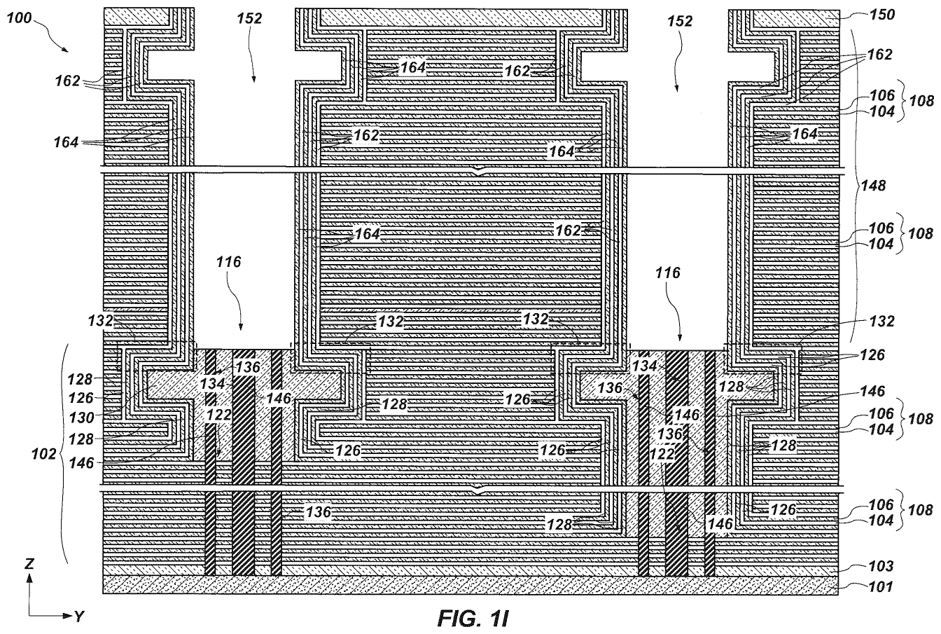

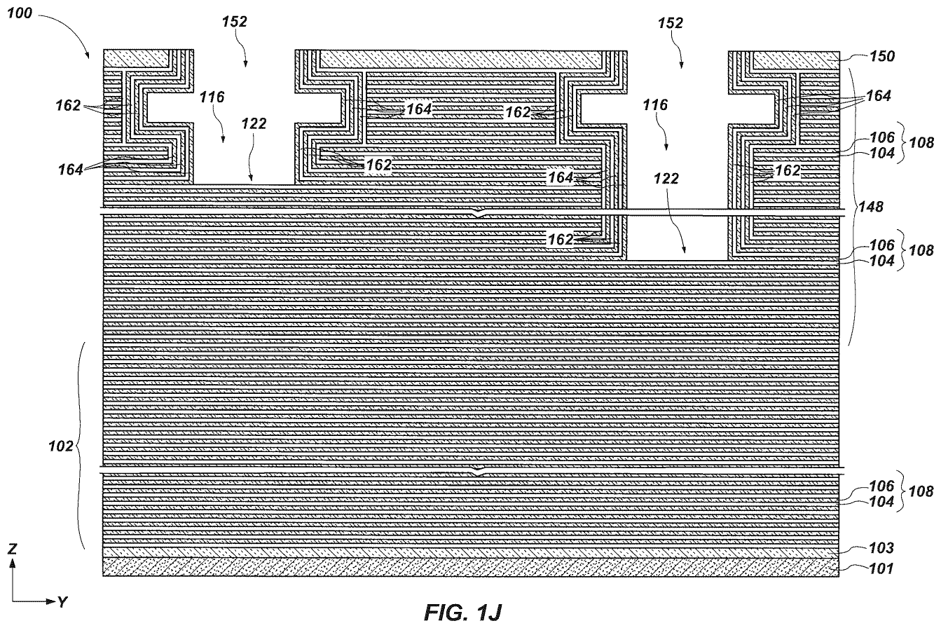

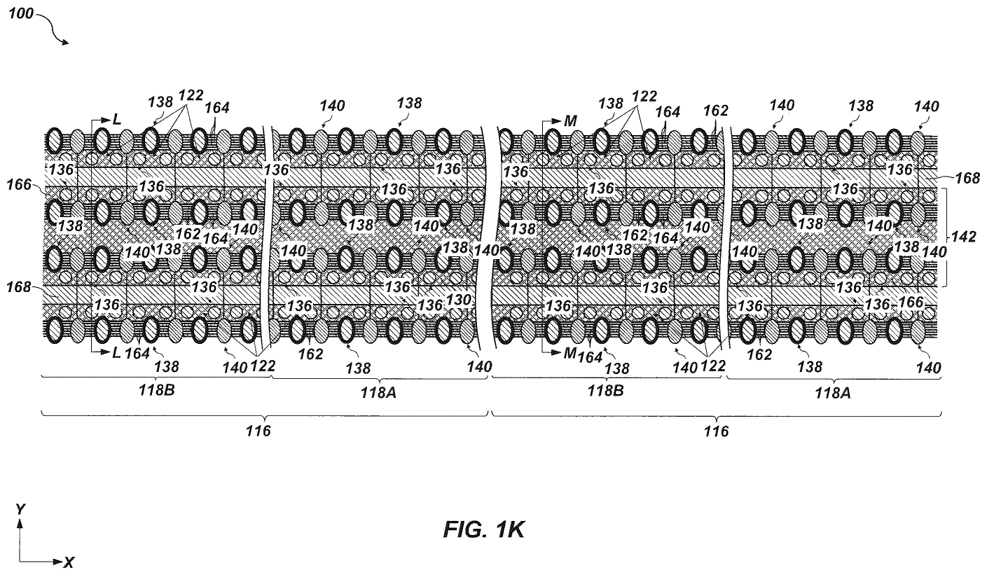

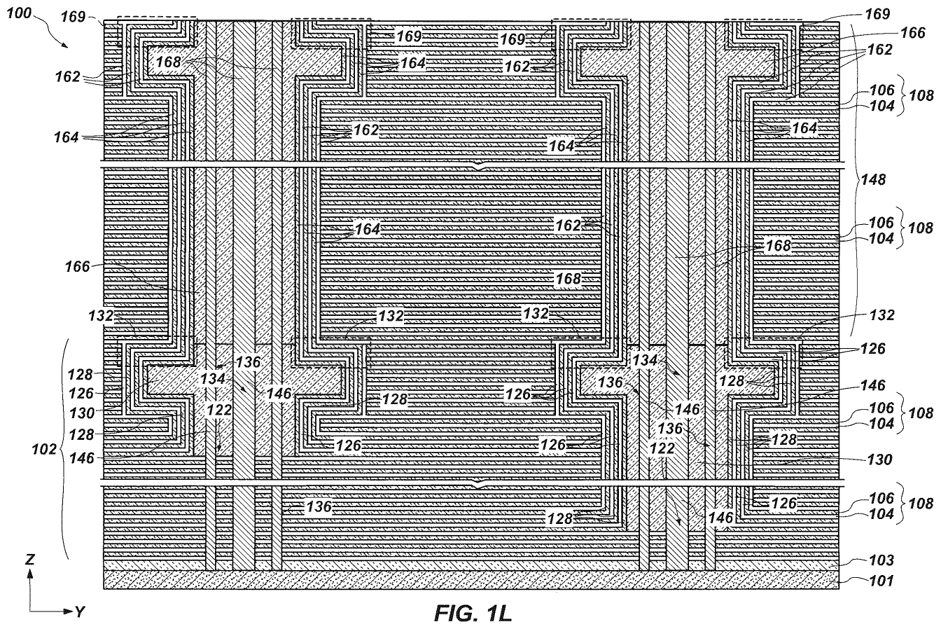

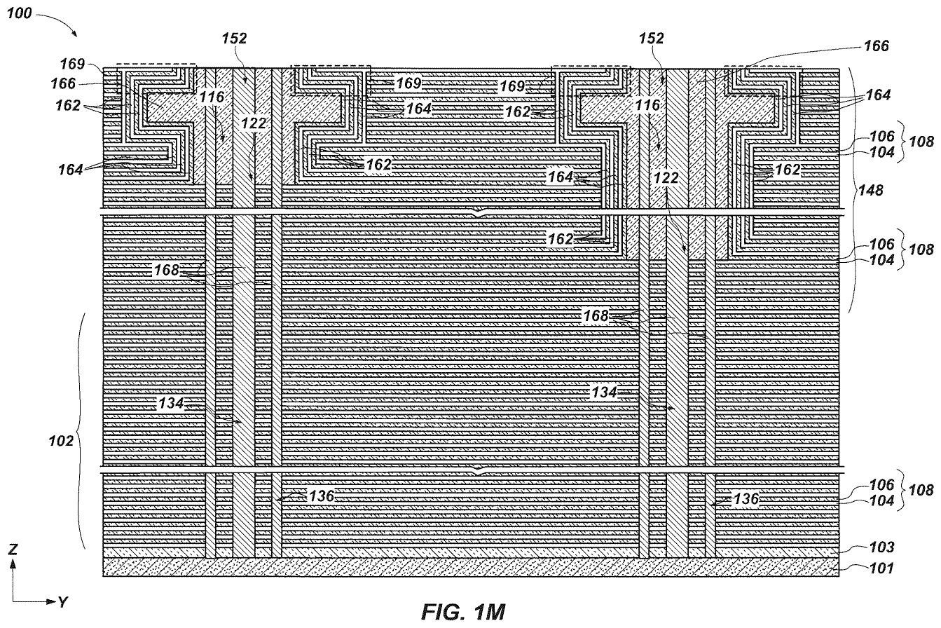

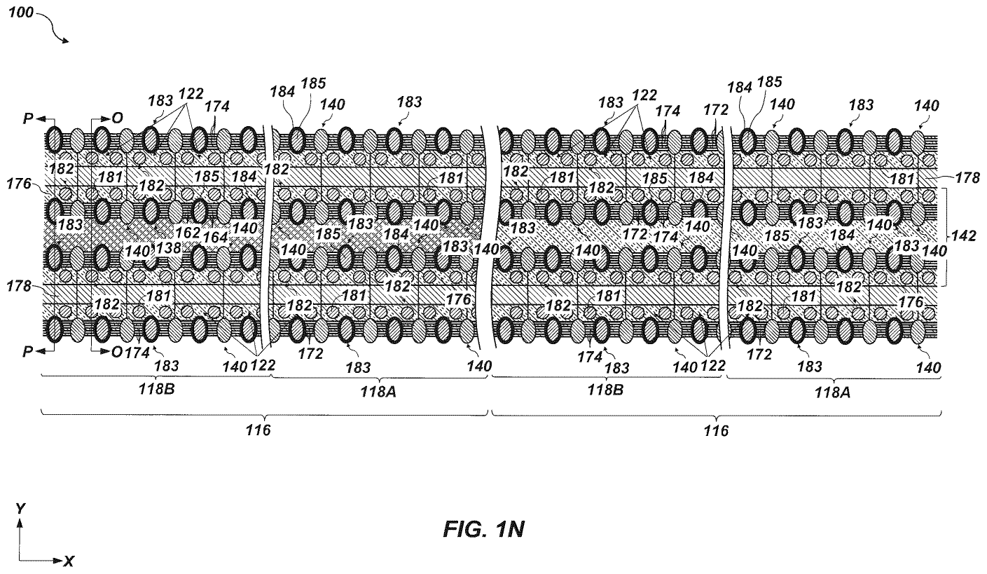

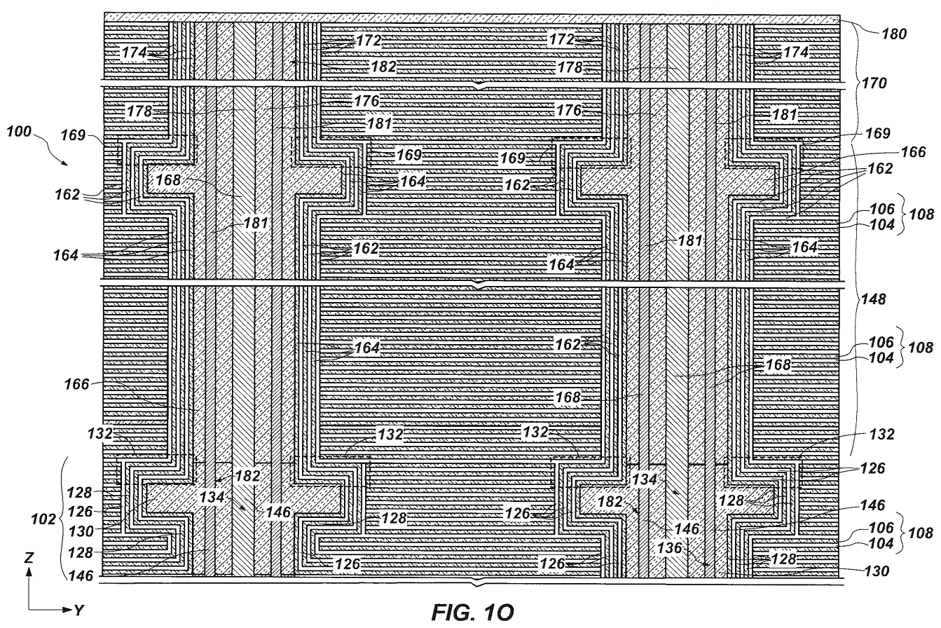

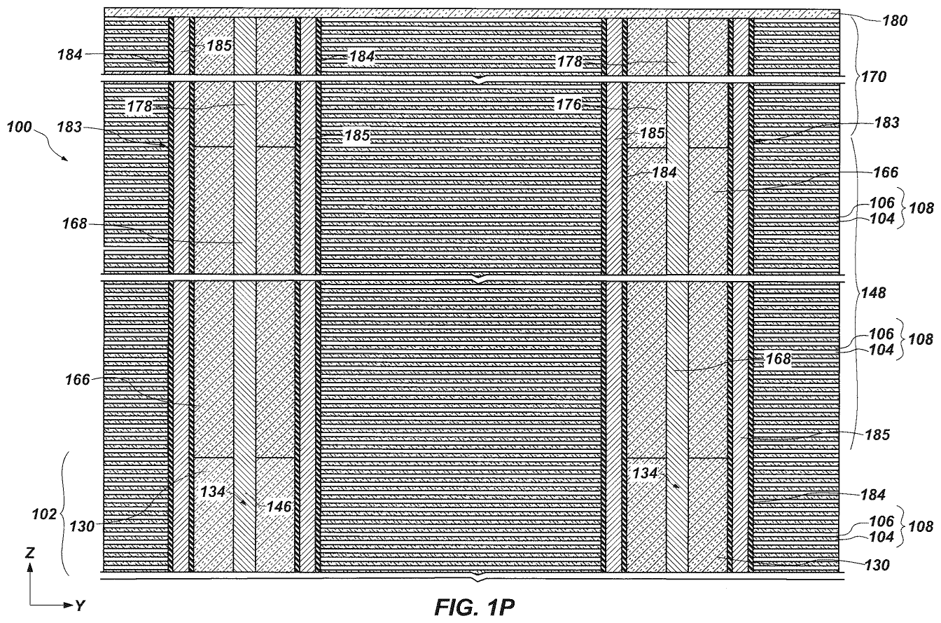

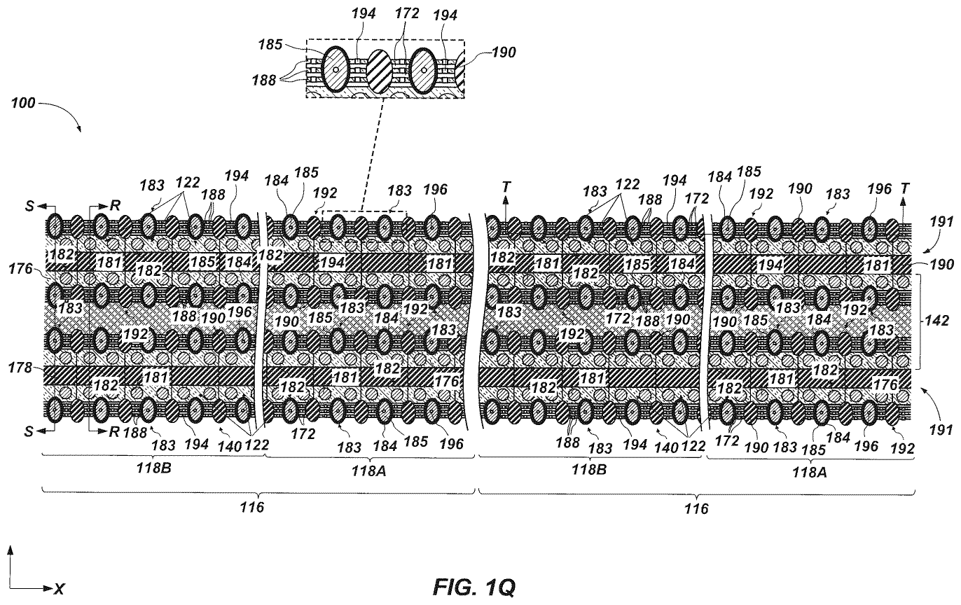

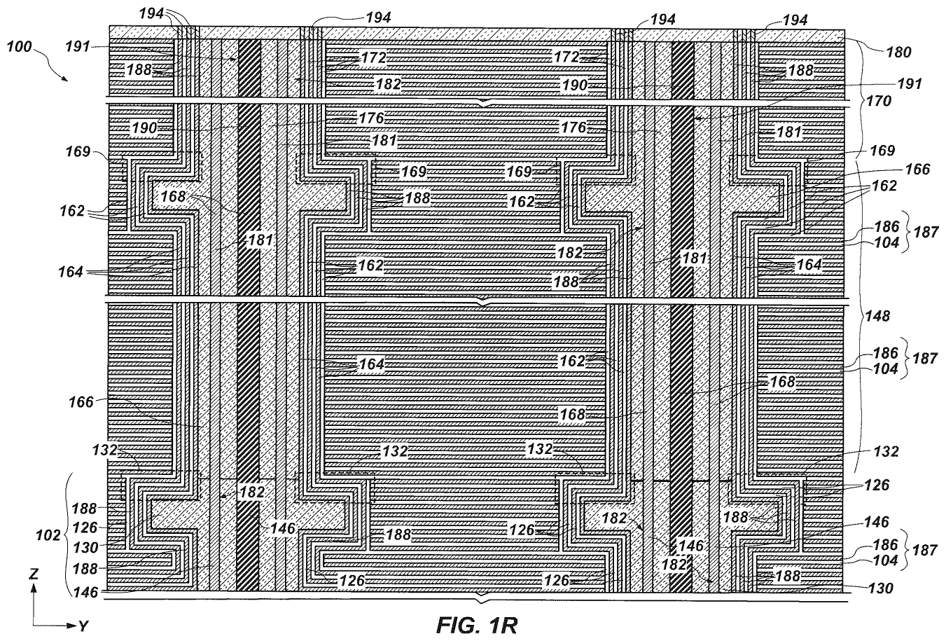

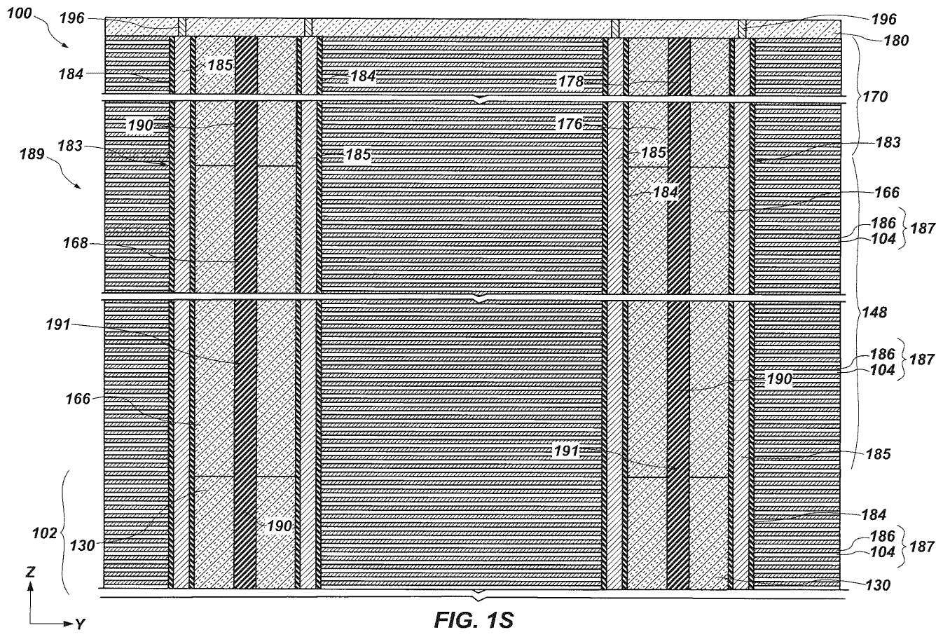

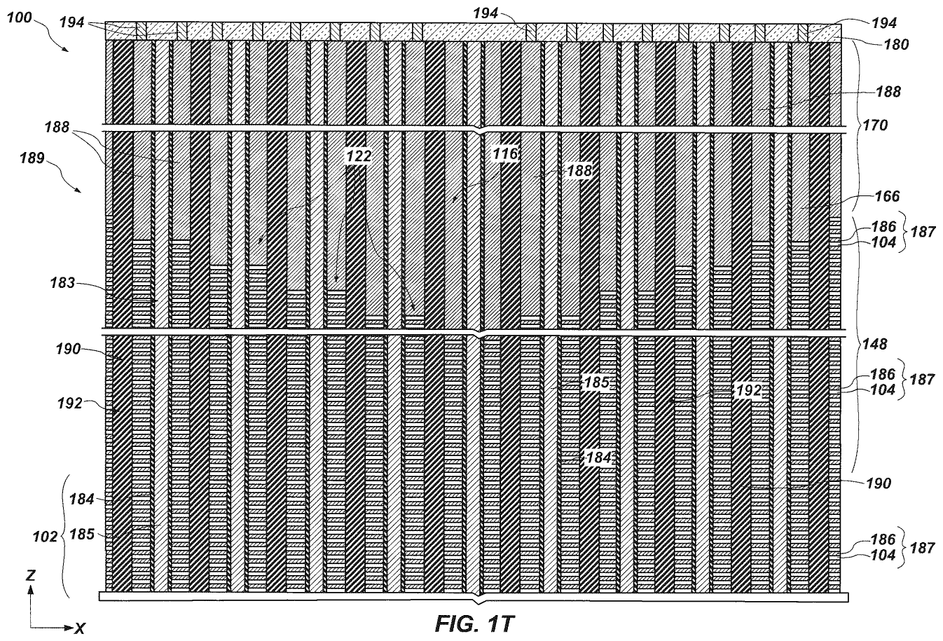

FIG. 1A through FIG. 1T are various views (described in further detail below) illustrating a microelectronic device structure at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device.

FIG. 1A is a simplified, partial cross-sectional view of a microelectronic device structure 100, in accordance with embodiments of the disclosure. As shown in FIG. 1A, the microelectronic device structure 100 may be formed to include a first deck structure 102 including a vertically alternating (e.g., in a Z-direction) sequence of insulative structures 104 and sacrificial structure 106 arranged in tiers 108. Each of the tiers 108 of the first deck structure 102 may individually include the sacrificial structure 106 vertically neighboring (e.g., directly vertically adjacent) the insulative structure 104.

The tiers 108 of the vertically alternating (e.g., in a Z-direction) sequence of insulative structures 104 and sacrificial structures 106 may vertically overlie (e.g., in the Z-direction) a source structure 101. The source structure 101 may comprise, for example, at least one conductive material, such as one or more of a metal (e.g., W, Ti, Mo, Nb, V, Hf, Ta, Cr, Zr, Fc, Ru, Os, Co, Rh, Ir, Ni, Pa, Pt, Cu, Ag, Au, Al), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy), a conductive metal-containing material (e.g., a conductive metal nitride, a conductive metal silicide, a conductive metal carbide, a conductive metal oxide), or a doped semiconductor material (e.g., a semiconductor material doped with one or more P-type dopants (e.g., polysilicon doped with at least one P-type dopant, such as one or more of boron, aluminum, and gallium) or one or more N-type conductivity materials (e.g., polysilicon doped with at least one N-type dopant, such as one or more of arsenic, phosphorous, antimony, and bismuth)). In some embodiments, the source structure 101 comprises conductively-doped silicon.

In some embodiments, the source structure 101 further comprises one or more of metal silicide material (e.g., tungsten silicide (WSiₓ)), metal nitride material (e.g., tungsten nitride), and metal silicon nitride material (e.g., tungsten silicon nitride (WSiₓN_{y})).

The insulative structure 104 of each of the tiers 108 of the first deck structure 102 may be formed of and include at least one insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In some embodiments, the insulative structure 104 of each of the tiers 108 of the first deck structure 102 is formed of and includes a dielectric oxide material, such as SiOₓ (e.g., SiO₂). The insulative structure 104 of each of the tiers 108 may be substantially homogeneous, or the insulative structure 104 of one or more (e.g., each) of the tiers 108 may be heterogeneous.

The sacrificial structure 106 of each of the tiers 108 of the first deck structure 102 may be formed of and include at least one material (e.g., at least one insulative material) that may be selectively removed relative to the insulative structure 104. The sacrificial structure 106 may be selectively etchable relative to the insulative structure 104 during common (e.g., collective, mutual) exposure to a first etchant; and the insulative structure 104 may be selectively etchable to the sacrificial structure 106 during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. By way of non-limiting example, depending on the material composition of the insulative structure 104, the sacrificial structure 106 may be formed of and include one or more of at least one dielectric oxide material (e.g., one or more of AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H₂), at least one dielectric carboxynitride material (e.g., SiOₓC₂N_{y}), and at least one semiconductive material (e.g., polycrystalline silicon). In some embodiments, the sacrificial structure 106 of each of the tiers 108 of the first deck structure 102 is formed of and includes a dielectric nitride material, such as SiN_{y} (e.g., Si₃N₄). The sacrificial structure 106 may, for example, be selectively etchable relative to the insulative structure 104 during common exposure to a wet etchant comprising phosphoric acid (H₃PO₄).

The first deck structure 102 may be formed to include any desired number of the tiers 108. By way of non-limiting example, the first deck structure 102 may be formed to include greater than or equal to sixteen (16) of the tiers 108, such as greater than or equal to thirty-two (32) of the tiers 108, greater than or equal to sixty-four (64) of the tiers 108, greater than or equal to one hundred and twenty-eight (128) of the tiers 108, or greater than or equal to two hundred and fifty-six (256) of the tiers 108. FIG. 1A includes a break line within the first deck structure 102 to indicate that the first deck structure 102 includes a greater number of tiers 108 than those illustrated.

In some embodiments, an etch stop material 103 vertically (e.g., in the Z-direction) intervenes between the source structure 101 and the first deck structure 102. The etch stop material 103 may be formulated and configured to be selectively etchable with respect to the tiers 108 of the insulative structures 104 and the sacrificial structures 106 after, for example, forming staircase structures (e.g., staircase structures 118 (FIG. 1D)) within the first deck structure 102. The etch stop material 103 may comprise, for example, one or more of magnesium oxide, cerium oxide, and aluminum oxide.

Trenches 110 may be formed through a number of the tiers 108. As described in further detail herein, the vertical depth (e.g., in the Z-direction) of the trenches 110 may facilitate formation of conductive contacts structures (e.g., conductive contact structures 188 (FIG. 1Q, FIG. 1R, FIG. 1T)) on conductive structures (e.g., conductive structure 186 (FIG. 1R through FIG. 1S)) during subsequent processing acts.

In some embodiments, the trenches 110 are formed through a number of the tiers 108. In FIG. 1A, the trenches 110 are illustrated as being formed through nine (9) of the tiers 108. However, the disclosure is not so limited, and the trenches 110 may be formed through a greater quantity or a lesser quantity of the tiers 108. In some embodiments, levels of the insulative structures 104 are exposed at the vertically lower (e.g., in the Z-direction) portions of the trenches 110.

With continued reference to FIG. 1A, a mask material 112 may vertically overlie (e.g., in the Z-direction) the first deck structure 102. The mask material 112 may be formed of and include, for example, polysilicon. In some embodiments, the mask material 112 further includes a carbon nitride material vertically overlying (e.g., in the Z-direction) the polysilicon.

FIG. 1B is a simplified partial cross-sectional view of the microelectronic device structure 100 at a processing stage subsequent to that illustrated in FIG. 1A. After forming the trenches 110, portions of sidewalls of the sacrificial structures 106 exposed within the trenches 110 may be selectively horizontally removed (e.g., in the Y-direction) with respect to the insulative structures 104.

The sacrificial structures 106 may be selectively removed by, for example, exposing the sacrificial structures to a wet etch process, such as one or more of phosphoric acid (H₃PO₄), nitric acid (HNO₃), hydrofluoric acid (HF), and ethylene glycol ((CH₂OH)₂). In other embodiments, the sacrificial structures 106 may be exposed to a dry etch process (e.g., a reactive ion etch (RIE) process), such as one or more of trifluoromethane (CHF₃), difluoromethane (CH₂F₂), hexafluoroethane (C₂F₆), silicon tetrafluoride (SiF₄), sulfur hexafluoride (SF₆), chlorine trifluoride (ClF₃), and dichlorodifluoromethane (CCl₂F₂).

After horizontally removing the portions of the sacrificial structures 106, exposed portions of the insulative structures 104 may be selectively horizontally removed (e.g., in the Y-direction) with respect to the sacrificial structures 106. In some embodiments, removal of the portions of the insulative structures 104 may remove exposed levels of the insulative structures 104 at vertically lower (e.g., in the Z-direction) portions of the openings and expose the sacrificial structures 106.

The insulative structures 104 may be selectively removed by, for example, exposing the insulative structures 104 to a dry etch process (e.g., a reactive ion etch (RIE) process) and exposing the insulative structures 104 to one or more of ammonia (NH₃), nitrogen trifluoride (NF₃), carbon tetrafluoride (CF₄), trifluoromethane (CHF₃), oxygen (O₂), hydrogen (H₂), and hydrogen fluoride (HF). In other embodiments, the insulative structures 104 are removed by exposing the insulative structures 104 to a wet etch process including one or more of hydrofluoric acid (HF), ammonium fluoride (NH₄F), and acetic acid (CH₃COOH).

In some embodiments, the levels of the sacrificial structures 106 and the levels of the insulative structures 104 are removed in multiple acts. In some such embodiments, portions of a first number of the levels of the sacrificial structures 106 are removed, followed by removal of portions of corresponding levels of the insulative structures 104. After removing the portions of the first levels of the sacrificial structures 106 and the insulative structures 104, portions of additional levels of the sacrificial structures 106 and the insulative structures 104 are removed until a portion of a desired quantity of levels of the sacrificial structures 106 and the insulative structures 104 have been removed.

After removing the portions of the levels of the sacrificial structures 106 and the insulative structures 104, a spacer material 114 may be formed in recessed portions of the trenches 110. The spacer material 114 may be formed at regions where the portions of the levels of the sacrificial structures 106 and the insulative structures 104 were removed and may vertically underlie (e.g., in the Z-direction) the mask material 112.

In some embodiments, the spacer material 114 is formed of and includes, for example, one or more of the materials described above with reference to the etch stop material 103, such as one or more of aluminum oxide, magnesium oxide, and cerium oxide. In some embodiments, the spacer material 114 comprises aluminum oxide.

FIG. 1C is a simplified partial cross-sectional view of the microelectronic device structure 100 at a processing stage subsequent to that illustrated in FIG. 1B. FIG. 1D is a simplified partial cross-sectional view of the microelectronic device structure 100 taken through section line D-D of FIG. 1C.

With collective reference to FIG. 1C and FIG. 1D, the first deck structure 102 may be formed to include stadium structures 116 therein. The stadium structures 116 may include opposing staircase structures 118, and a central region 120 (FIG. 1D) horizontally interposed between (e.g., in the X-direction) the opposing staircase structures 118. FIG. 1C illustrates a step 122 of two stadium structures 116 and FIG. 1D illustrates portions of opposing staircase structures 118 of one stadium structure 116.

The opposing staircase structures 118 of each stadium structure 116 may include a forward staircase structure 118A and a reverse staircase structure 118B. A phantom line extending from a top of the forward staircase structure 118A to a bottom of the forward staircase structure 118A may have a positive slope, and another phantom line extending from a top of the reverse staircase structure 118B to a bottom of the reverse staircase structure 118B may have a negative slope. In additional embodiments, the stadium structure 116 may exhibit a different configuration than that depicted in FIG. 1D. As a non-limiting example, the stadium structure 116 may be modified to include a forward staircase structure 118A but not a reverse staircase structure 118B (e.g., the reverse staircase structure 118B may be absent), or the stadium structure 116 may be modified to include a reverse staircase structure 118B but not a forward staircase structure 118A (e.g., the forward staircase structure 118A may be absent).

The opposing staircase structures 118 (e.g., the forward staircase structure 118A and the reverse staircase structure 118B) of an individual stadium structure 116 each include steps 122 defined by edges (e.g., horizontal ends) of the tiers 108 of the first deck structure 102. With reference to FIG. 1D, in some embodiments, each step 122 is defined by horizontal edges (e.g., in the X-direction) of more than one tier 108 (e.g., multiple tiers 108), such as three tiers 108.

For the opposing staircase structures 118 of an individual stadium structure 116, each step 122 of the forward staircase structure 118A may have a counterpart step 122 within the reverse staircase structure 118B having substantially the same geometric configuration (e.g., shape, dimensions), vertical position (e.g., in the Z-direction), and horizontal distance (e.g., in the X-direction) from a horizontal center (e.g., in the X-direction) of the central region 120 of the stadium structure 116. In additional embodiments, at least one step 122 of the forward staircase structure 118A does not have a counterpart step 122 within the reverse staircase structure 118B having substantially the same geometric configuration (e.g., shape, dimensions), vertical position (e.g., in the Z-direction), and/or horizontal distance (e.g., in the X-direction) from horizontal center (e.g., in the X-direction) of the central region 120 of the stadium structure 116; and/or at least one step 122 of the reverse staircase structure 118B does not have a counterpart step 122 within the forward staircase structure 118A having substantially the same geometric configuration (e.g., shape, dimensions), vertical position (e.g., in the Z-direction), and/or horizontal distance (e.g., in the X-direction) from horizontal center (e.g., in the X-direction) of the central region 120 of the stadium structure 116.

Each of the stadium structures 116 of the first deck structure 102 may individually include a desired quantity of steps 122. Each of the stadium structures 116 may include substantially the same quantity of steps 122 as each other of the stadium structures 116, or at least one of the stadium structures 116 may include a different quantity of steps 122 than at least one other of the stadium structures 116. In some embodiments, at least one of the stadium structures 116 includes a different (e.g., greater, lower) quantity of steps 122 than at least one other of the stadium structures 116. As shown in FIG. 1D, in some embodiments, the steps 122 of each of the stadium structures 116 are arranged in order, such that steps 122 directly horizontally adjacent (e.g., in the X-direction) one another correspond to a group of tiers 108 of the first deck structure 102 (e.g., multiple tiers 108, such as three tiers 108, as illustrated in FIG. 1D) directly vertically adjacent (e.g., in the Z-direction) another group of tiers 108 (e.g., without vertically intervening (e.g., in the Z-direction) tiers 108). In additional embodiments, the steps 122 of at least one of the stadium structures 116 are arranged out of order, such that at least some steps 122 of the stadium structure 116 directly horizontally adjacent (e.g., in the X-direction) one another correspond to tiers 108 of first deck structure 102 not directly vertically adjacent (e.g., in the Z-direction) one another.

The stadium structures 116, the staircase structures 118, and the steps 122 may be formed by, for example, forming a mask structure over the first deck structure 102; removing a portion of the mask structure to form openings in the mask structure and expose portions of a number of the tiers 108 (e.g., three of the tiers 108) that will correspond to a first step 122 of each of the staircase structures 118 to be formed; removing a portion of the exposed tiers 108 of the insulative structures 104 and the sacrificial structures 106 through the openings; removing a portion of the mask structure (e.g., horizontally trimming (e.g., in the X-direction) the mask structure) to expose an additional portion of the tiers 108; removing the exposed portions of the tiers 108 through the openings in the mask structure; and repeating the acts of removing additional portions of the mask structure and additional exposed portions of the tiers 108. In some embodiments, an additional mask structure (e.g., a chop mask) is formed over some of the staircase structures 118 and portions of the staircase structures 118 remaining exposed are removed to form steps 122 of the exposed staircase structures 118 having a relatively vertically lower (e.g., in the Z-direction) height than the steps 122 of the staircase structures 118 covered by the additional mask structure. While the stadium structures 116, the staircase structures 118, and the steps 122 have been described as being formed by a particular method, the disclosure is not so limited, and the stadium structures 116, the staircase structures 118, and the steps 122 may be formed by methods other than those described herein.

With reference to FIG. 1C, in some embodiments, forming the stadium structures 116 including the staircase structures 118 includes forming neighboring (e.g., in the Y-direction) stadium structures 116 to include steps 122 having a different vertical height (e.g., in the Z-direction) than one another.

After forming the stadium structures 116, the spacer material 114 (FIG. 1B) may be removed to form recesses 124 (FIG. 1C) within the stadium structures 116 and vertically overlying (e.g., in the Z-direction) the steps 122. In some embodiments, one or more tiers 108 of the insulative structures 104 and the sacrificial structures 106 may be removed through the opening in the mask material 112. In some embodiments, exposed portions of the tiers 108 within the stadium structures 116 may comprise one of the insulative structures 104.

FIG. 1E is a simplified partial cross-sectional view of the microelectronic device structure 100 at a processing stage subsequent to that illustrated in FIG. 1C and FIG. 1D. After removing the spacer material 114 (FIG. 1B) and forming the recesses 124 (FIG. 1C), sequential pairs of insulative liner materials 126 and sacrificial liner materials 128 may be formed on vertically extending (e.g., in the Z-direction) sidewalls of the stadium structures 116.

The sequential insulative liner materials 126 and sacrificial liner materials 128 may be formed by, for example, forming a first insulative liner material 126 on vertically extending (e.g., in the Z-direction) sidewalls of the stadium structures 116 and removing the horizontally extending (e.g., in the X-direction, in the Y-direction) portions of the insulative liner material 126 and the vertically underlying (e.g., in the Z-direction) insulative structure 104 to expose the vertically underlying (e.g., in the Z-direction) sacrificial structure 106. A first sacrificial liner material 128 may be formed over the first insulative liner material 126 and the exposed sacrificial structure 106 and horizontally extending (e.g., in the X-direction, in the Y-direction) portions of the sacrificial liner material 128 and the vertically underlying (e.g., in the Z-direction) sacrificial structure 106 may be removed to expose the vertically underlying (e.g., in the Z-direction) insulative structure 104.

After forming the first sacrificial liner material 128 and removing the vertically underlying (e.g., in the Z-direction) sacrificial structure 106, a second insulative liner material 126 may be formed over the first sacrificial liner material 128; the horizontally extending portions (e.g., in the X-direction, in the Y-direction) of the second insulative liner material 126 and the vertically underlying (e.g., in the Z-direction) insulative structure 104 may be removed to expose the vertically underlying (e.g., in the Z-direction) sacrificial structure 106; a second sacrificial liner material 128 may be formed over the second insulative liner material 126 and the exposed sacrificial structure 106; and the horizontally extending (e.g., in the X-direction, in the Y-direction) portions of the second sacrificial liner material 128 and the sacrificial structure 106 may be removed. The sequential acts of forming the insulative liner material 126, removing horizontally extending portions (e.g., in the X-direction, in the Y-direction) of the insulative liner material 126 and the exposed insulative structure 104 to expose the vertically underlying (e.g., in the Z-direction) sacrificial structure 106, forming the sacrificial liner material 128 over the insulative liner material 126 and the exposed portion of the sacrificial structure 106, and removing the horizontally extending (e.g., in the X-direction, in the Y-direction) portions of the sacrificial liner material 128 and the vertically underlying (e.g., in the Z-direction) sacrificial structure 106 may be repeated a desired number of times to form a desired quantity of pairs of the insulative liner materials 126 and the sacrificial liner materials 128.

In some embodiments, the quantity of pairs of the insulative liner materials 126 and the sacrificial liner materials 128 corresponds to the quantity of tiers 108 of the insulative structures 104 and sacrificial structures 106 defining each of the steps 122 (FIG. 1D) of the staircase structures 118 (FIG. 1D). Although FIG. 1E illustrates three (3) pairs of the insulative liner materials 126 and the sacrificial liner materials 128, the disclosure is not so limited. In other embodiments, the quantity of pairs of the insulative liner materials 126 and the sacrificial liner materials 128 may be less than three (e.g., two), or greater than three (e.g., four, five, six) depending on the number of tiers 108 of the insulative structures 104 and the sacrificial structures 106 defining the steps 122.

After forming the desired quantity of pairs of the insulative liner materials 126 and the sacrificial liner materials 128, a level of the insulative structures 104 may be exposed on the steps 122 and a sacrificial liner material 128 may be present on vertically extending (e.g., in the Z-direction) sidewalls of the staircase structures 118. The level of the insulative structure 104 defining a vertically upper (e.g., in the Z-direction) surface of each step 122 may isolate the sacrificial liner materials 128 on horizontally opposing (e.g., in the Y-direction) sides of the stadium structures 116.

With continued reference to FIG. 1E, in some embodiments, the sacrificial liner materials 128 at horizontal edges (e.g., in the Y-direction) of the steps 122 are in contact with the sacrificial structures 106 defining a horizontal edge (e.g., in the X-direction) of a step 122 with a vertically upper (e.g., in the Z-direction) surface vertically above (e.g., in the Z-direction) the sacrificial structures 106. Accordingly, the sacrificial liner materials 128 illustrated in FIG. 1E are in contact with the sacrificial structures 106 defining the step 122 directly vertically (e.g., in the Z-direction) above the step 122 illustrated in FIG. 1E.

The insulative liner materials 126 may be formed of and include one or more of the materials described above with reference to the insulative structures 104. In some embodiments, the insulative liner materials 126 comprise substantially the same material composition as the insulative structures 104. In some embodiments, the insulative liner materials 126 comprise silicon dioxide.

The sacrificial liner materials 128 may be formed of and include one or more of the materials described above with reference to the sacrificial structures 106. In some embodiments, the sacrificial liner materials 128 comprise substantially the same material composition as the sacrificial structures 106. In some embodiments, the sacrificial liner materials 128 comprise silicon nitride.

FIG. 1F is a simplified partial top-down view illustrating a portion of the microelectronic device structure 100 at a processing stage subsequent to that illustrated in FIG. 1E. FIG. 1G is a simplified partial cross-sectional view of the microelectronic device structure 100 taken through section line G-G of FIG. 1F. FIG. 1F includes break lines at horizontal edges (e.g., in the X-direction) to indicate that the microelectronic device structure 100 horizontally extends (e.g., in the X-direction) and includes structures (e.g., steps 122, stadium structures 116) in addition to those that are illustrated.

With reference to FIG. 1F and FIG. 1G, after forming the pairs of the insulative liner materials 126 and the sacrificial liner materials 128, the trenches 110 (FIG. 1E) may be filled with an insulative material 130 and the microelectronic device structure 100 may be exposed to a removal process, such as a chemical mechanical planarization (CMP) process to remove horizontally extending (e.g., in the X-direction, in the Y-direction) portions of the insulative material 130 from a vertically uppermost (e.g., in the Z-direction) surface of the microelectronic device structure 100.

The insulative material 130 may be formed of and include insulative material, such as one or more of the materials described above with reference to the insulative structures 104. In some embodiments, the insulative material 130 comprises substantially the same material composition as the insulative structures 104. In some embodiments, the insulative material 130 comprises silicon dioxide.

After forming the insulative material 130 and exposing the microelectronic device structure 100 to the removal (e.g., polishing) process, the mask material 112 (FIG. 1E) may be removed to expose the vertically uppermost (e.g., in the Z-direction) level of the insulative structures 104. In some embodiments, after removing the mask material 112, an oxide material may be formed over the microelectronic device structure 100 (e.g., at locations corresponding to the removed mask material 112) and the oxide material and the vertically uppermost (e.g., in the Z-direction) level of the insulative structures 104 may be removed to expose the vertically uppermost (e.g., in the Z-direction) level of the sacrificial structures 106. The oxide material and the vertically uppermost (e.g., in the Z-direction) level of the insulative structures 104 may be removed by, for example, CMP. In some embodiments, the oxide material may facilitate forming a planar vertically uppermost surface of the microelectronic device structure 100 to facilitate removal of the vertically uppermost level of the insulative structures 104 since the vertically uppermost surface of the microelectronic device structure 100 may not be substantially planar after removal of the mask material 112 (e.g., portions of the insulative liner materials 126 and the sacrificial liner materials 128 may vertically extend (e.g., in the Z-direction) above the surfaces of the tiers 108 of the insulative structures 104 and the sacrificial structures 106).

With reference to FIG. 1G, removing the vertically uppermost (e.g., in the Z-direction) level of the insulative structures 104 and exposing the vertically uppermost (e.g., in the Z-direction) level of the sacrificial structures 106 may form contact connection regions 132 (illustrated in dashed boxes in FIG. 1G) wherein a conductive path between levels of conductive structures (e.g., conductive structures 186 (FIG. 1R through FIG. 1S)) and conductive contact structures (e.g., conductive contact structures 188 (FIG. 1Q, FIG. 1R, FIG. 1T)) to be formed from the respective sacrificial structures 106 and sacrificial liner materials 128 may be connected to a vertically upper surface of the microelectronic device structure 100.

With continued reference to FIG. 1F and FIG. 1G, slot structure openings 134 may be formed vertically through (e.g., in the Z-direction) the first deck structure 102; support pillar openings 136 may be formed vertically through (e.g., in the Z-direction) the first deck structure 102; contact pillar openings 138 may be formed vertically through (e.g., in the Z-direction) the first deck structure 102; and replacement gate openings 140 may be formed vertically through (e.g., in the Z-direction) the first deck structure 102.

With reference to FIG. 1F, the slot structure openings 134 may separate the microelectronic device structure 100 into block structures 142. Each block structure 142 may include stadium structures 116 on each horizontal side (e.g., in the Y-direction) of a bridge region 144 horizontally centered (e.g., in the Y-direction) the block structure 142. In some embodiments, the bridge region 144 comprises a greater vertical height (e.g., in the Z-direction) of the tiers 108 of the first deck structure 102 than the other portions of the block structure 142, such as the stadium structures 116. In some embodiments, a vertical height (e.g., in the Z-direction) of steps 122 of stadium structures 116 on opposing horizontal sides (e.g., in the Y-direction) of the bridge region 146 within the same block structure 142 may be different. In some embodiments, each slot structure opening 134 horizontally intervenes (e.g., in the Y-direction) horizontally neighboring (e.g., in the Y-direction) stadium structures 116 or horizontally neighboring (e.g., in the Y-direction) block structures 142.

At least a portion of each of the support pillar openings 136 may individually be formed within horizontal boundaries (e.g., in the Y-direction) of the block structures 142, such as within horizontal boundaries (e.g., in the Y-direction) of the staircase structures 118 of the stadium structures 116. In some such embodiments, the support pillar openings 136 do not horizontally extend into (e.g., in the Y-direction) outside of horizontal boundaries (e.g., in the Y-direction) of the stadium structures 116 and do not horizontally extend (e.g., in the Y-direction) into horizontal boundaries (e.g., in the Y-direction) of the bridge region 144.

In some embodiments, two support pillar openings 136 vertically extend (e.g., in the Z-direction) through the insulative material 130 and the first deck structure 102 vertically underlying (e.g., in the Z-direction) and within horizontal boundaries (e.g., in the X-direction, in the Y-direction) of each step 122.

Each of the contact pillar openings 138 and the replacement gate openings 140 may individually include a portion located within horizontal boundaries (e.g., in the Y-direction) of the stadium structures 116 and an additional portion located within horizontal boundaries (e.g., in the Y-direction) of the bridge region 144. In some such embodiments, the contact pillar openings 138 and the replacement gate openings 140 individually include portions outside of horizontal boundaries (e.g., in the Y-direction) of the stadium structures 116. In some embodiments, the contact pillar openings 138 and the replacement gate openings 140 individually horizontally extend through (e.g., in the Y-direction) the sequential pairs of insulative liner materials 126 and sacrificial liner materials 128. In some such embodiments, the contact pillar openings 138 and the replacement gate openings 140 individually horizontally separate (e.g., in the X-direction) different portions of the sequential pairs of insulative liner materials 126 and sacrificial liner materials 128, such as portions of the sequential pairs of insulative liner materials 126 and sacrificial liner materials 128 in contact with tiers 108 of different steps 122.

The contact pillar openings 138 may be located within horizontal boundaries (e.g., in the X-direction) of the steps 122. In some embodiments, the contact pillar openings 138 are individually horizontally centrally located (e.g., in the X-direction) within each step 122. In some such embodiments, each of the contact pillar openings 138 is individually horizontally centrally located (e.g., in the X-direction) between edges of the tiers 108 defining the step 122 through which the contact pillar opening 138 vertically extends (e.g., in the Z-direction).

The replacement gate openings 140 may be located at the horizontal edges (e.g., in the X-direction) of the steps 122. In some such embodiments, the replacement gate openings 140 individually horizontally extend (e.g., in the X-direction) into two horizontally neighboring (e.g., in the X-direction) steps 122 and vertically extend (e.g., in the Z-direction) through portions of the two steps 122. In some embodiments, the replacement gate openings 140 horizontally separate (e.g., in the X-direction) the sequential pairs of insulative liner materials 126 and sacrificial liner materials 128 of horizontally neighboring (e.g., in the X-direction) steps 122.

With continued reference to FIG. 1F, the contact pillar openings 138 and the replacement gate openings 140 may be substantially horizontally aligned (e.g., in the Y-direction) with one another. In addition, in some embodiments, a contact pillar opening 138 may horizontally intervene (e.g., in the X-direction) between horizontally neighboring (e.g., in the X-direction) replacement gate openings 140; and a replacement gate opening 140 may horizontally intervene (e.g., in the X-direction) between horizontally neighboring (e.g., in the X-direction) contact pillar openings 138.

The contact pillar openings 138 and the replacement gate openings 140 may each individually exhibit a desired geometric configuration (e.g., dimensions and shape) and spacing. The geometric configurations and spacing of the contact pillar openings 138 and the replacement gate openings 140 may be selected at least partially based on the configurations and positions of other components (e.g., the steps 122 of the staircase structures 118, conductive contact structures to be formed in contact with the steps 122 of the staircase structures 118) of the microelectronic device structure 100. Each of the contact pillar openings 138 and the replacement gate openings 140 may individually exhibit substantially the same geometric configuration (e.g., the same dimensions and the same shape) and horizontal spacing (e.g., in the X-direction) as each of the other of the respective contact pillar openings 138 and replacement gate openings 140, or at least some of the contact pillar openings 138 and the replacement gate openings 140 may exhibit a different geometric configuration (e.g., one or more different dimensions, a different shape) and/or different horizontal spacing than at least some other of the respective contact pillar openings 138 and the replacement gate openings 140. In some embodiments, each of the contact pillar openings 138 and the replacement gate openings 140 are at least partially uniformly spaced in the X-direction and in the Y-direction.

In some embodiments, the contact pillar openings 138 each individually has a geometric configuration and spacing permitting the respective contact pillar openings 138 to vertically extend (e.g., in the Z-direction) through the first deck structure 102 and physically contact (e.g., land on) a structure of the source structure 101 to facilitate a predetermined function (e.g., an electrical interconnection function, a support function) of the respective contact pillar openings 138. In other embodiments, the contact pillar openings 138 do not include an electrical interconnection function and serve primarily (e.g., only) a support function.

In some embodiments, the replacement gate openings 140 vertically extend (e.g., in the Z-direction) through the first deck structure 102 and physically contact (e.g., land on) the etch stop material 103 to facilitate a predetermined function (e.g., a replacement gate function) of the respective replacement gate openings 140. In other embodiments, the replacement gate openings 140 physically contact the source structure 101.

In FIG. 1F, boundaries of the contact pillar openings 138 are illustrated in a thicker line relative to the boundaries of the replacement gate openings 140 to distinguish the contact pillar openings 138 from the replacement gate openings 140.

In some embodiments, a size and shape of the contact pillar openings 138 are substantially the same as a size and shape of the replacement gate openings 140. In other embodiments, one or both of the size and shape of the contact pillar openings 138 are different than the corresponding size and shape of the replacement gate openings 140.

With continued reference to FIG. 1F and FIG. 1G, each of the slot structure openings 134, the support pillar openings 136, the contact pillar openings 138, and the replacement gate openings 140 may be filled with a sacrificial material 146 and portions of the sacrificial material 146 on vertically uppermost (e.g., in the Z-direction) surfaces of the microelectronic device structure 100 may be removed, such as by exposing the microelectronic device structure 100 to a CMP process.

The sacrificial material 146 may be formed of and include, for example, one or more of polysilicon, a carbon-containing material (e.g., amorphous carbon, carbon nitride, silicon carbon nitride (SiCN)), and aluminum oxide. In some embodiments, the sacrificial material 146 comprises polysilicon.

Although FIG. 1F and FIG. 1G have been described and illustrated as including a particular configuration of the support pillar openings 136, the contact pillar openings 138, and the replacement gate openings 140, the disclosure is not so limited. In other embodiments, the configuration of the support pillar openings 136, the contact pillar openings 138, and the replacement gate openings 140 may be different than that described.

FIG. 1H is a simplified partial cross-sectional view of the microelectronic device structure 100 at a processing stage subsequent to that illustrated in FIG. 1F and FIG. 1G. A second deck structure 148 may be formed over the first deck structure 102 including the stadium structures 116 and the contact connection regions 132. The second deck structure 148 may include additional tiers 108 of insulative structures 104 and sacrificial structures 106 that are substantially the same as the tiers 108 of the insulative structures 104 and the sacrificial structures 106 of the first deck structure 102.

A quantity of the additional tiers 108 of the second deck structure 148 may be the same as, greater than, or less than the quantity of tiers 108 of the first deck structure 102. In some embodiments, the quantity of the additional tiers 108 of the second deck structure 148 is greater than the quantity of the tiers 108 of the first deck structure 102.

An additional mask material 150 may be formed over the additional tiers 108 of the second deck structure 148. The additional mask material 150 may comprise one or more of the materials described above with reference to the mask material 112 (FIG. 1A). In some embodiments, the additional mask material 150 comprises polysilicon.

With continued reference to FIG. 1H, trenches 152 may be formed through a quantity of the vertically uppermost (e.g., in the Z-direction) tiers 108. In some embodiments, the trenches 152 may be formed through nine (9) of the uppermost tiers 108, as described above with reference to FIG. 1A.

After forming the trenches 152, portions of the sacrificial structures 106 exposed within the trenches 152 may be selectively horizontally removed (e.g., in the Y-direction) with respect to the insulative structures 104, exposed portions of the insulative structures 104 may be selectively horizontally removed (e.g., in the Y-direction) with respect to the sacrificial structures 106, and a level of the insulative structures 104 at vertically lower (e.g., in the Z-direction) portions of the trenches 152 may be removed to expose the sacrificial structures 106 at the vertically lower portions of the trenches 152, as described above with reference to FIG. 1C.

A spacer material 154 may be formed within the trenches 152 and portions of the spacer material 154 may be removed through the trenches 152 in the mask material 150, leaving portions of the spacer material 154 vertically underlying the mask material 150 at regions where the portions of the insulative structures 104 and the sacrificial structures 106 were horizontally removed (e.g., in the Y-direction), as described above with reference to FIG. 1B.

The spacer material 154 may comprise one or more of the materials described above with reference to the spacer material 114 (FIG. 1A). In some embodiments, the spacer material 154 comprises aluminum oxide.

FIG. 1I is a simplified partial cross-sectional view of the microelectronic device structure 100 illustrating regions of the microelectronic device structure 100 including the previously formed stadium structures 116 described above with reference to FIG. 1C and FIG. 1D. FIG. 1J is a simplified partial cross-sectional view illustrating another region of the microelectronic device structure 100 in which additional stadium structures 116 are formed.

With collective reference to FIG. 1I and FIG. 1J, after forming the spacer material 154 (FIG. 1H), additional stadium structures 116 (FIG. 1J) including additional staircase structures 118 (FIG. 1J) may be formed within the second deck structure 148, as described above with reference to the stadium structures 116 and the staircase structures 118. The stadium structures 116 and the additional stadium structures 116 may simply be referred to herein as “stadium structures 116” and the staircase structures 118 and the additional staircase structures 118 may simply be referred to herein as “staircase structures 118.” The stadium structures 116 formed within the first deck structure 102 may be referred to herein as “first stadium structures 116” and the staircase structures 118 formed within the first deck structure 102 may be referred to herein as “first staircase structures 118.” The additional stadium structures 116 formed within the second deck structure 148 may be referred to herein as “second stadium structures 116” and the additional staircase structures 118 formed within the second deck structure 148 may be referred to herein as “second staircase structures 118.”

As described in further detail below (e.g., with reference to FIG. 1K), the additional stadium structures 116 may be horizontally spaced (e.g., in the X-direction) from the stadium structures 116. The additional staircase structures 118 of the additional stadium structures 116 may include additional steps 122 defined by the horizontal edges (e.g., in the X-direction) of the tiers 108 of the insulative structures 104 and the sacrificial structures 106 of the additional staircase structures 118.

A vertical height (e.g., in the Z-direction) of additional steps 122 of the additional staircase structures 118 may be vertically higher (e.g., in the Z-direction) than the steps 122 of the staircase structures 118 of the stadium structures 116 previously described with reference to FIG. 1C and FIG. 1D.

FIG. 1I illustrates the portions of the previously formed stadium structures 116, described above with reference to FIG. 1C and FIG. 1D. In some embodiments, after forming the additional stadium structures 116 (FIG. 1I, FIG. 1J), the levels of the insulative structures 104 and the sacrificial structures 106 of the additional tiers 108 are removed through the trenches 152 (FIG. 1H) to expose portions of the sequential insulative liner materials 126 and sacrificial liner materials 128 within the contact connection regions 132, the insulative material 130, and the sacrificial material 146 of the slot structure openings 134, the support pillar openings 136, the contact pillar openings 138, and the replacement gate openings 140. In some embodiments, exposing the portions of the sequential insulative liner materials 126 and sacrificial liner materials 128 within the contact connection regions 132 includes forming the trenches 152 (FIG. 1H) to have a greater dimension (e.g., in the Y-direction) than the trenches 110 (FIG. 1C).

With continued reference to FIG. 1I, after exposing the contact connection regions 132, additional insulative liner materials 162 and additional sacrificial liner materials 164 may be formed on vertical (e.g., in the Z-direction) sidewalls of the trenches 152 (FIG. 1H), as described above with reference to the sequential insulative liner materials 126 and sacrificial liner materials 128. By way of non-limiting example, a first additional insulative liner material 162 may be formed within the trenches 152 and on vertical sidewalls of the trenches 152. After forming the first additional insulative liner material 162, horizontally extending portions (e.g., in the X-direction, in the Y-direction) of the first additional insulative liner material 162 on exposed surfaces of the trenches 152 may be removed, exposing the vertically underlying (e.g., in the Z-direction) insulative material 130 and the sacrificial material 146; and leaving the vertically extending (e.g., in the Z-direction) portions of the first additional insulative liner material 162 on the sidewalls of the trenches 152.

A first additional sacrificial liner material 164 may be formed on vertical sidewalls of the first additional insulative liner material 162. After forming the first additional sacrificial liner material 164, horizontally extending portions (e.g., in the X-direction, in the Y-direction) of the first additional sacrificial liner material 164 at exposed portions of the trenches 152 may be removed, exposing the vertically underlying (e.g., in the Z-direction) insulative material 130 and the sacrificial material 146 and leaving the vertically extending (e.g., in the Z-direction) portions of the first additional sacrificial liner material 164 on the sidewalls of the first additional insulative liner material 162. The process of sequentially forming the additional insulative liner material 162; removing horizontally extending portions (e.g., in the X-direction, in the Y-direction) of the additional insulative liner material 162; forming the additional sacrificial liner material 164; and removing horizontally extending portions (e.g., in the X-direction, in the Y-direction) of the additional sacrificial liner material 164 may be repeated a desired number of times, which may correspond to a number of tiers 108 defining each of the steps 122.

FIG. 1J illustrates the additional stadium structures 116 including the additional staircase structures 118 having the additional steps 122 at a different vertical height (e.g., in the Z-direction) than the steps 122 of the staircase structures 118.

FIG. 1K is a simplified partial top down view of the microelectronic device structure 100 at a processing stage subsequent to that illustrated in FIG. 1I and FIG. 1J. The simplified top down view of FIG. 1K illustrates a larger portion of the microelectronic device structure 100 than that illustrated in the top down view of FIG. 1F to illustrate the staircase structures 118 formed in the first deck structure 102, as described above with reference to FIG. 1C and FIG. 1D, and the additional staircase structures 118 formed in the second deck structure 148. FIG. 1L is a simplified partial cross-sectional view of the microelectronic device structure 100 taken through section line L-L of FIG. 1K. FIG. 1M is a simplified partial cross-sectional view of the microelectronic device structure 100 taken through section line M-M of FIG. 1K.

With collective reference to FIG. 1K through FIG. 1M, after forming the sequential additional insulative liner materials 162 and the additional sacrificial liner material 164, the additional mask material 150 (FIG. 1I, FIG. 1J) may be removed from surfaces of the microelectronic device structure 100; an oxide material may be formed over the microelectronic device structure 100 (e.g., at locations corresponding to the removed mask material 150) and the oxide material and the vertically uppermost (e.g., in the Z-direction) level of the insulative structures 104 may be removed (such as by CMP) to expose the vertically uppermost (e.g., in the Z-direction) level of the sacrificial structures 106; an additional insulative material 166 may be formed within the trenches 152 (FIG. 1I, FIG. 1J) over the staircase structures 118 (FIG. 1K) and additional staircase structures 118 (FIG. 1K) and over the sacrificial material 146; the additional insulative material 166 may be patterned to form openings vertically over (e.g., in the Z-direction) and within horizontal boundaries (e.g., in the X-direction, in the Y-direction) of each of the slot structure openings 134, the support pillar openings 136, the contact pillar openings 138 (FIG. 1K), and the replacement gate openings 140 (FIG. 1K) may be formed through the additional insulative material 166; additional sacrificial material 168 may be formed within the openings; and portions of the additional sacrificial material 168 may be removed from horizontally extending (e.g., in the X-direction, in the Y-direction) of the microelectronic device structure 100.

The additional insulative material 166 include one or more of the materials described above with reference to the insulative material 130. In some embodiments, the additional insulative material 166 comprises substantially the same material composition as the insulative material 130. In some embodiments, the additional insulative material 166 comprises silicon dioxide.

With reference to FIG. 1L, the additional insulative material 166 vertically overlying (e.g., in the Z-direction) and within horizontal boundaries (e.g., in the X-direction, in the Y-direction) of the stadium structures 116 within the first deck structure 102 may be patterned to form openings exposing the vertically uppermost (e.g., in the Z-direction) surfaces of the vertically underlying (e.g., in the Z-direction) sacrificial material 146 within each of the slot structure openings 134, the support pillar openings 136, the contact pillar openings 138, and the replacement gate openings 140. In some embodiments, the additional insulative material 166 is patterned in the same manner as described above with reference to FIG. 1F and FIG. 1G and the patterning of the insulative material 130 for forming the slot structure openings 134, the support pillar openings 136, the contact pillar openings 138, and the replacement gate openings 140. In addition, with reference to FIG. 1M, the additional insulative material 166 within the additional stadium structures 116 formed within the second deck structure 148 may be patterned to form slot structure openings 134, the support pillar openings 136, the contact pillar openings 138, and the replacement gate openings 140 within the second stadium structures 116.

In some embodiments, the insulative material 130 does not vertically overlie (e.g., in the Z-direction) and is not located within horizontal boundaries (e.g., in the X-direction, in the Y-direction) of the additional stadium structures 116 within the second deck structure 148, since the second deck structure 148 and the additional stadium structures 116 thereof are formed after forming the insulative material 130 vertically over (e.g., in the Z-direction) and within horizontal boundaries (e.g., in the X-direction, in the Y-direction) of the stadium structures 116 within the first deck structure 102.

After forming the openings and exposing the vertically uppermost (e.g., in the Z-direction) surfaces of the sacrificial material 146 of the slot structure openings 134, the support pillar openings 136, the contact pillar openings 138, and the replacement gate openings 140, the openings may be filled with the additional sacrificial material 168 and horizontally extending (e.g., in the X-direction, in the Y-direction) portions of the additional sacrificial material 168 may be removed, such as by CMP.

After removal of the horizontally extending (e.g., in the X-direction, in the Y-direction) portions of the additional sacrificial material 168, a vertically uppermost (e.g., in the Z-direction) level of the sacrificial structures 106 may be exposed and contact connection regions 169 (illustrated in dashed boxes in FIG. 1L) may be exposed wherein a conductive path between levels of conductive structures (e.g., conductive structures 186 (FIG. 1R through FIG. 1S)) to be formed from the sacrificial structures 106 and conductive contact structures (e.g., conductive contact structures 188 (FIG. 1Q, FIG. 1R, FIG. 1T)) to be formed from the additional sacrificial liner materials 164 may be connected to a vertically upper surface of the microelectronic device structure 100.

The additional sacrificial material 168 may be formed of and include one or more of the materials described above with reference to the sacrificial material 146. In some embodiments, the additional sacrificial material 168 comprises substantially the same material composition as the sacrificial material 146. In other embodiments, the additional sacrificial material 168 comprises a different material composition than the sacrificial material 146. In some embodiments, the additional sacrificial material 168 comprises polysilicon.

In some embodiments, the sacrificial material 146 does not vertically overlie (e.g., in the Z-direction) and is not located within horizontal boundaries (e.g., in the X-direction, in the Y-direction) of the additional stadium structures 116 formed within the second deck structure 148 formed after forming the sacrificial material 146 vertically over (e.g., in the Z-direction) and within horizontal boundaries (e.g., in the X-direction, in the Y-direction) of the stadium structures 116.

FIG. 1K does not illustrate all of the steps 122 of the first stadium structures 116 or all of the additional steps 122 of the second stadium structures 116 for clarity and case of understanding the description. For example, FIG. 1K includes break lines in each of the first stadium structures 116 and the second stadium structures 116 to indicate that each of the first stadium structures 116 and the second stadium structures includes additional steps 122.

FIG. 1N is a simplified partial top down view of the microelectronic device structure 100 at a processing stage subsequent to that illustrated in FIG. 1K through FIG. 1M. FIG. 1O is a simplified partial cross-sectional view of the microelectronic device structure 100 taken through section line O-O of FIG. 1N. FIG. 1P is a simplified partial cross-sectional view of the microelectronic device structure 100 taken through section line P-P of FIG. 1N.

With reference to FIG. 1O and FIG. 1P, after forming the additional sacrificial material 168 within the openings in the additional insulative material 166 and removing the horizontally extending (e.g., in the X-direction, in the Y-direction) portions of the additional sacrificial material 168, a third deck structure 170 including of additional tiers 108 of additional insulative structures 104 and additional sacrificial structures 106 may be formed vertically overlying (e.g., in the Z-direction) the second deck structure 148. A number of the tiers 108 of the third deck structure 170 may be substantially the same as the number of the tiers 108 of the second deck structure 148. In other embodiments, the number of the tiers 108 of the third deck structure 170 is less or greater than the number of the tiers 108 of the second deck structure 148.

As described above with reference to formation of the additional insulative liner materials 162 and the additional sacrificial liner materials 164, openings may be formed through portions of the tiers 108 of the third deck structure 170 (e.g., within horizontal boundaries (e.g., in the X-direction, in the Y-direction) of the additional insulative material 166) to expose the additional insulative material 166, vertically uppermost (e.g., in the Z-direction) surfaces of the additional sacrificial material 168, and the contact connection regions 169; and sequential further insulative liner materials 172 and further additional sacrificial materials 174 may be formed on vertical (e.g., in the Z-direction) sidewalls of the openings in the tiers 108 of the third deck structure 170 and in contact with the respective the additional insulative liner materials 162 and the additional sacrificial liner materials 164 at the contact connection regions 169.

The further insulative liner materials 172 and further additional sacrificial materials 174 may be substantially the same as the respective additional insulative liner materials 162 and the additional sacrificial liner materials 164.

After forming the further insulative liner materials 172 and further additional sacrificial materials 174, a further additional insulative material 176 may be formed within the openings and vertically over (e.g., in the Z-direction) the exposed surfaces of the additional insulative material 166 and the additional sacrificial material 168, as described above with reference to formation of the additional insulative material 166.

The additional insulative material 176 may be formed of and include insulative material, such as one or more of the materials described above with reference to the insulative material 130. In some embodiments, the further additional insulative material 176 comprises substantially the same material composition as the insulative material 130. In some embodiments, the further additional insulative material 176 comprises silicon dioxide.

As described above with reference to formation of the additional sacrificial material 168 within the slot structure openings 134, the support pillar openings 136 (FIG. 1K through FIG. 1M), the contact pillar openings 138 (FIG. 1K), and the replacement gate openings 140 (FIG. 1K), openings may be formed in the further additional insulative material 176 vertically over (e.g., in the Z-direction) and within horizontal boundaries (e.g., in the X-direction, in the X-direction, in the Y-direction) of the slot structure openings 134, the support pillar openings 136, the contact pillar openings 138, and the replacement gate openings 140. The openings may be filled with a further additional sacrificial material 178 to vertically extend (e.g., in the Z-direction) the slot structure openings 134, the support pillar openings 136, the contact pillar openings 138, and the replacement gate openings 140 to a vertically uppermost (e.g., in the Z-direction) surface of the microelectronic device structure 100.

The further additional sacrificial material 178 may be formed of and include one or more of the materials described above with reference to the sacrificial material 146. In some embodiments, the further additional sacrificial material 178 comprises polysilicon.

After forming the additional sacrificial material 178, an oxide material 180 may be formed vertically over (e.g., in the Z-direction) of the microelectronic device structure 100. The oxide material 180 may comprise one or more of the materials described above with reference to the insulative structures 104. In some embodiments, the oxide material 180 comprises silicon dioxide. For clarity and case of understanding the description, and to more clearly illustrate the relative location of the materials and structures vertically underlying (e.g., in the Z-direction) the oxide material 180, the oxide material 180 is not illustrated in FIG. 1N.

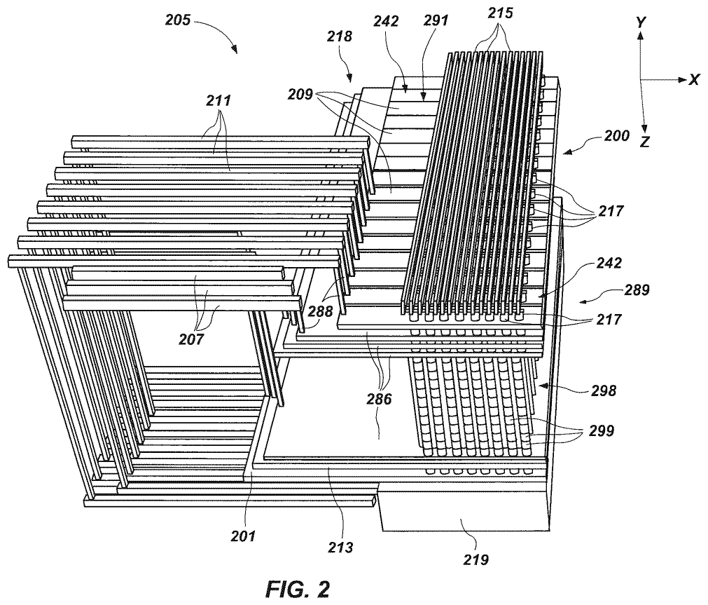

After forming the oxide material 180, pillars of memory cell materials may be formed within a memory array region of the microelectronic device structure 100. The memory cells materials may form vertical strings of memory cells (e.g., vertical strings 298 (FIG. 2) of memory cells 299 (FIG. 2)) after a replacement gate process, as described in further detail herein.

With continued reference to FIG. 1N and FIG. 1O, after forming the pillars of memory cell materials, the further additional sacrificial material 178, the additional sacrificial material 168, and the sacrificial material 146 may be removed (e.g., exhumed) from the support pillar openings 136 (FIG. 1M) and the support pillar openings 136 may be filled with an insulative material 181 to form support pillars 182.

The insulative material 181 may be formed of and include insulative material, such as one or more of the materials described above with reference to the insulative structures 104. In some embodiments, the insulative material 181 comprises silicon dioxide.

In some embodiments, vertically uppermost (e.g., in the Z-direction) stadium structures (e.g., stadium structures formed within the third deck structure 170) are sub-divided with additional slot structures comprising an insulative material vertically extending (e.g., in the Z-direction) through the vertically uppermost stadium structures to form sub-block structures and to facilitate formation of select gate drain (SGD) contacts within each of the sub-block structures.

Referring to FIG. 1N and FIG. 1P, after forming the support pillars 182, the further additional sacrificial material 178, the additional sacrificial material 168, and the sacrificial material 146 may be removed (e.g., exhumed) from the contact pillar openings 138 (FIG. 1K) and pillar structures 183 may be formed vertically through the microelectronic device structure 100 at the locations corresponding to the locations of the contact pillar openings 138.

The pillar structures 183 may vertically extend (e.g., in the Z-direction) through the microelectronic device structure 100 and contact, for example, the source structure 101 (FIG. 1L, FIG. 1M), as described above with reference to the contact pillar openings 138 (FIG. 1K). In some embodiments, at least some of the pillar structures 183 are in electrical communication with a structure (e.g., a CMOS structure) underlying the source structure 101.

The pillar structures 183 may individually include, for example, a liner material 184 on vertical sidewalls (e.g., in the Z-direction) thereof and an additional material 185 in a central portion of the pillar structure 183. The liner material 184 may substantially surround (e.g., substantially horizontally and vertically cover) sidewalls of the additional material 185.

The additional material 185 may be formed of and include at least one conductive material, such as such as one or more of at least one metal (e.g., W, Ti, Mo, Nb, V, Hf, Ta, Cr, Zr, Fe, Ru, Os, Co, Rh, Ir, Ni, Pa, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, a stainless steel), at least one conductive metal-containing material (e.g., a conductive metal nitride, a conductive metal silicide, a conductive metal carbide, a conductive metal oxide), and at least one conductively-doped semiconductor material (e.g., conductively-doped Si, conductively-doped Ge, conductively-doped SiGe). In some embodiments, the additional material 185 of each of the pillar structures 183 has substantially the same material composition. In some embodiments, the additional material comprises tungsten.

In other embodiments, the additional material 185 is formed of and includes at least one insulative material. In some such embodiments, the additional material 185 is formed of and includes at least one dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the additional material 185 comprise silicon dioxide. In some embodiments, such as where the additional material 185 comprises an insulative material, the microelectronic device structure 100 does not include the liner material 184 on sidewalls of the additional material 185 and the pillar structures 183 may comprise only the additional material 185 (e.g., the insulative material).

The liner material 184 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the liner material 184 comprises SiO₂. In some embodiments, the liner material 184 comprises a material composition that is not substantially removed responsive to exposure to etch chemistries formulated and configured to remove silicon nitride.

After forming the pillar structures 183, the pillar structures 183 may be covered with the oxide material 180. In some embodiments, additional oxide material 180 is formed vertically over (e.g., in the Z-direction) the pillar structures 183 and the microelectronic device structure 100 is exposed to a CMP process.

FIG. 1Q is a simplified partial top-down view illustrating the microelectronic device structure 100 at a processing stage subsequent to that illustrated in FIG. 1N through FIG. 1P. FIG. 1R is a simplified partial cross-sectional view of the microelectronic device structure 100 taken through section line R-R of FIG. 1Q. FIG. 1S is a simplified partial cross-sectional view of the microelectronic device structure 100 taken through section line S-S of FIG. 1Q. FIG. 1T is a simplified partial cross-sectional view of the microelectronic device structure 100 taken through section line T-T of FIG. 1Q.

With reference to FIG. 1Q through FIG. 1T, openings may be formed through the oxide material 180 to expose the sacrificial material 146 (FIG. 1O, FIG. 1P), the additional sacrificial material 168 (FIG. 1O, FIG. 1P), and the further additional sacrificial material 178 (FIG. 1N through FIG. 1P) of the slot structure openings 134 and the replacement gate openings 140 (FIG. 1N). The sacrificial material 146, the additional sacrificial material 168, and the further additional sacrificial material 178 may be selectively removed (e.g., exhumed) with respect to the insulative structures 104, the sacrificial structures 106, the insulative materials 130, the additional insulative material 166, and the further additional insulative material 176 through the slot structure openings 134 and the replacement gate openings 140.

After removing the sacrificial material 146 (FIG. 1O, FIG. 1P), the additional sacrificial material 168 (FIG. 1O, FIG. 1P), and the further additional sacrificial material 178 (FIG. 1N through FIG. 1P), the sacrificial structures 106 (FIG. 1N through FIG. 1P) may be selectively removed (e.g., exhumed) with respect to the insulative structures 104 through the slot structure openings 134 and the replacement gate openings 140 in a so-called replace gate process. After removing the sacrificial structures 106, conductive structures 186 comprising conductive material may be formed at locations corresponding to the locations of the sacrificial structures 106. At least a portion of the sacrificial structures 106 are replaced with the conductive structures 186 through the replacement gate openings 140. Forming the conductive structures 186 forms a stack structure 189 comprising tiers 187 of a vertically alternating sequence of insulative structures 104 and the conductive structures 186.

Concurrently with removing the sacrificial structures 106 and replacing the sacrificial structures 106 with the conductive structures 186, the sacrificial liner materials 128 (FIG. 1N, FIG. 1O), the additional sacrificial liner materials 164 (FIG. 1N, FIG. 1O), and the further additional sacrificial materials 174 (FIG. 1N, FIG. 1O) may be selectively removed (e.g., exhumed) with respect to the insulative liner materials 126, the additional insulative liner materials 162, and the further additional insulative liner materials 172 through the replacement gate openings 140 and replaced with conductive material to form conductive contact structures 188 vertically extending (e.g., in the Z-direction) from horizontal edges (e.g., in the Y-direction) of the steps 122 and the staircase structures 118 of each of the first deck structure 102, the second deck structure 148, and the third deck structure 170 to a vertically uppermost (e.g., in the Z-direction) surface of the microelectronic device structure 100, such as a vertically uppermost (e.g., in the Z-direction) surface of the third deck structure 170.

After forming the conductive materials of the conductive structures 186 and the conductive contact structures 188 through the slot structure openings 134 (FIG. 1N through FIG. 1P) and the replacement gate openings 140 (FIG. 1N), the slot structure openings 134 and the replacement gate openings 140 may individually be filled with an insulative material 190 to form slot structures 191 and additional pillar structures 192 at locations corresponding to the respective slot structure openings 134 and the replacement gate openings 140.

The insulative material 190 may be formed of and include one or more of the materials described above with reference to the insulative structures 104. In some embodiments, the insulative material 190 comprises silicon dioxide.

FIG. 1T illustrates a portion of a second stadium structure 116 within the second deck structure 148. With reference to FIG. 1Q and FIG. 1T, each of the steps 122 may be defined by horizontal edges (e.g., in the X-direction) of multiple tiers 187 of the insulative structures 104 and the conductive structures 186. With reference to FIG. 1Q, each of the steps 122 is in contact with (e.g., electrical communication with) six of the conductive contact structures 188 at horizontal ends (e.g., in the Y-direction) of the steps 122. In some embodiments, the conductive structure 186 of each tier 187 of each of the steps 122 is in contact with two of the conductive contact structures 188, such as at opposite horizontal ends (e.g., in the X-direction) of a pillar structure 183.

With reference to FIG. 1R, a vertically uppermost (e.g., in the Z-direction) of each step 122 may be defined by a vertically uppermost (e.g., in the Z-direction) level of an insulative structure 104 defining the step 122. With reference to FIG. 1T, the conductive contact structures 188 contact the step 122 at the insulative structure 104 and horizontally extend (e.g., in the X-direction) along the step 122 between one of the pillar structures 183 and a horizontally neighboring (e.g., in the X-direction) additional pillar structure 192. Referring to FIG. 1R, the conductive contact structures 188 may individually be located outside of horizontal boundaries (e.g., in the Y-direction) of the vertically uppermost (e.g., in the Z-direction) insulative structure 104 defining the steps 122.

With reference to FIG. 1Q and FIG. 1T, in some embodiments, each of the conductive contact structures 188 individually comprises a larger dimension in a first horizontal direction (e.g., in the X-direction, such as the direction in which the steps 122 vertically (e.g., in the Z-direction) ascend and descend) greater than a dimension of the respective step 122 in a second horizontal direction (e.g., in the Y-direction).

In some embodiments, a shape of the conductive contact structures 188 is substantially plate like. For example, in some embodiments, the conductive contact structures 188 individually have a greater dimension in a first horizontal direction (e.g., in the X-direction, in the direction of the vertically ascending and descending steps 122) than in a second horizontal direction (e.g., in the Y-direction, in a horizontal direction substantially perpendicular to the steps 122).

In some embodiments, the conductive contact structures 188 in contact with the conductive structures 186 of each of the steps 122 are horizontally aligned (e.g., in the X-direction) with one another in a first horizontal direction, such as the horizontal direction in which the steps 122 vertically (e.g., in the Z-direction) ascend and descend. In some such embodiments, the conductive contact structures 188 in contact with the conductive structures 186 of different levels of the conductive structures 186 defining a particular step 122 are horizontally aligned (e.g., in the Y-direction) with one another in a first horizontal direction (e.g., in the X-direction) and are horizontally offset from one another in a second horizontal direction (e.g., in the Y-direction). In some embodiments, the conductive contact structures 188 in contact with the same conductive structure 186 of the same levels of the conductive structures 186 of the same step 122 are horizontally aligned with one another in the second horizontal direction (e.g., in the Y-direction) and horizontally offset from one another in the first horizontal direction (e.g., in the X-direction).

With reference to FIG. 1Q and FIG. 1R, the conductive contact structures 188 are located outside of horizontal boundaries (e.g., in the Y-direction) of the slot structures 191 and the additional insulative materials 130, 166, 176 vertically overlying (e.g., in the Z-direction) the steps 122. Referring to FIG. 1T, the conductive contact structures 188 may horizontally extend (e.g., in the X-direction) substantially continuously from the pillar structures 183 to the horizontally neighboring (e.g., in the X-direction) additional pillar structure 192 at the horizontal edge (e.g., in the X-direction) step 122.

For each particular step 122, the vertically lowermost (e.g., in the Z-direction) conductive structure 186 defining step 122 may be in contact with a conductive contact structure 188 that is closer (e.g., in the Y-direction) to a horizontal center (e.g., in the Y-direction) of the staircase structures 118 than the conductive contact structure 188 in contact with the vertically uppermost (e.g., in the Z-direction) conductive structure 186 defining the step 122. In some such embodiments, as the vertical height (e.g., in the Z-direction) of conductive structures 186 of a particular step 122 increases, the distance from the horizontal center (e.g., in the Y-direction) of the conductive contact structure 188 with which the conductive structure 186 is in contact increases.

In addition, conductive contact structures 188 in contact with vertically lower (e.g., in the Z-direction) conductive structures 186 defining the step 122 are horizontally closer (e.g., in the Y-direction) to the slot structure 191 than the conductive contact structures 188 in contact with vertically upper (e.g., in the Z-direction) conductive structures 186 defining the step 122. The conductive contact structures 188 in contact with vertically higher (e.g., in the Z-direction) conductive structures 186 of the steps 122 are located horizontally closer (e.g., in the Y-direction) to the bridge region 144 and horizontally farther (e.g., in the Y-direction) from the slot structure 191 than the conductive contact structures 188 in contact with the vertically lower conductive structures 186 of the steps 122. In some embodiments, the conductive contact structures 188 in contact with vertically higher (e.g., in the Z-direction) conductive structures 186 of the steps 122 are located nearer a horizontal boundary (e.g., in the Y-direction) of the block structures 142 than the conductive contact structures 188 in contact with vertically lower (e.g., in the Z-direction) conductive structures 186 of the steps 122.

With reference to FIG. 1R, each of the conductive contact structures 188 may vertically extend (e.g., in the Z-direction) from a step 122 and may include a contact connection region (e.g., the contact connection regions 132, 169) wherein the conductive contact structures 188 individually horizontally extend (e.g., in the Y-direction) more than at other regions of the conductive contact structures 188.

With reference to FIG. 1Q and FIG. 1T, conductive interconnect structures 194 may be formed through the oxide material 180 and in contact with (e.g., in electrical communication with) the conductive contact structures 188. In some embodiments, the conductive interconnect structures 194 are located within horizontal boundaries (e.g., in the X-direction) of the support pillars 182.

With reference to FIG. 1Q and FIG. 1S, additional conductive interconnect structures 196 may be formed within the oxide material 180 and in contact with (e.g., in electrical communication with) the additional material 185 of the pillar structures 183. The additional conductive interconnect structures 196 may be located within horizontal boundaries (e.g., in the X-direction, in the Y-direction) of the pillar structures 183. In some embodiments, the additional conductive interconnect structures 196 are substantially centrally located within the horizontal boundaries of the pillar structures 183.

The conductive interconnect structures 194 and the additional conductive interconnect structures 196 may individually be formed of and include conductive material, such as one or more of the materials described above with reference to the conductive contact structures 188. In some embodiments, the conductive interconnect structures 194 and the additional conductive interconnect structures 196 individually comprise substantially the same material composition as the conductive contact structures 188. In some embodiments, the conductive interconnect structures 194 and the additional conductive interconnect structures 196 individually comprise tungsten.

The conductive structures 186 and the conductive contact structures 188 may individually be formed of and include conductive material, such as one or more of the materials described above with reference to the additional material 185. In some embodiments, the conductive structures 186 and the conductive contact structures 188 individually comprise tungsten.

Forming the steps 122 to each individually comprise multiple tiers 187 of the conductive structures 186 and the insulative structures 104, and forming multiple conductive contact structures 188 from the sacrificial liner materials 128, the additional sacrificial liner materials 164, and the further additional sacrificial materials 174 facilitates forming the microelectronic device structure 100 with fewer steps 122 compared to conventional methods of forming a microelectronic device structure including the same number of conductive structures. In addition, the conductive contact structures 188 may be formed in-situ, without a separate act for forming the conductive contact structures in contact with the conductive structures after forming the conductive structures, reducing a number of deposition and etch acts for forming the microelectronic device structure 100 compared to conventional methods of forming microelectronic device structures.

Although FIG. 1A through FIG. 1T have been described and illustrated as including three deck structures (e.g., the first deck structure 102, the second deck structure 148, and the third deck structure 170), the disclosure is not so limited. In other embodiments, the microelectronic device structure 100 may be formed from a greater quantity of deck structures to facilitate forming a stack structure having a desired quantity of tiers 187 of conductive structures 186 and insulative structures 104.

Thus, in accordance with some embodiments of the disclosure, a microelectronic device comprises a stack structure comprising a vertically alternating sequence of conductive structures and insulative structures arranged in tiers, a staircase structure comprising steps comprising horizontal edges of the tiers, each of the steps comprising multiple tiers, and conductive contact structures vertically extending from a vertically upper surface of the stack structure to the conductive structures of the steps, the conductive structures defining each of the steps individually in contact with a conductive contact structure.

Microelectronic device structures (e.g., the microelectronic device structure 100 previously described with reference to FIG. 1A through FIG. 1T) of the disclosure may be included in microelectronic devices of the disclosure. For example, FIG. 2 illustrates a partial cutaway perspective view of a microelectronic device 205 (e.g., a memory device, such as a 3D NAND Flash memory device) including a microelectronic device structure 200. The microelectronic device structure 200 may be substantially similar to of the microelectronic device structure 100 previously described with reference to FIG. 1A through FIG. 1T. In FIG. 2 and the associated description, functionally similar features (e.g., structures, materials) are referred to with similar reference numerals incremented by 100. To avoid repetition, not all features shown in FIG. 2 are described in detail herein. Rather, unless described otherwise below, a feature designated by a reference numeral that is a 100 increment of the reference numeral of a previously described feature will be understood to be substantially similar to the previously described feature. By way of non-limiting example, unless described otherwise below, a feature designated by the reference numeral 186 in FIG. 2 will be understood to be substantially similar to the conductive structures 186 previously described herein with reference to FIG. 1A through FIG. 1T. In addition, for clarity and case of understanding the drawings and associated description, some features (e.g., structures, materials) of the microelectronic device structure 100 previously described herein are not shown in FIG. 2. However, it will be understood that any features of the microelectronic device structure 100 previously described with reference to FIG. 1A through FIG. 1T may be included in the microelectronic device structure 200 of the microelectronic device 205 described herein with reference to FIG. 2.

As shown in FIG. 2, in addition to the features of the microelectronic device structure 200 previously described herein in relation to the microelectronic device structure 100 (FIG. 1A through FIG. 1T), the microelectronic device 205 may further include vertical strings 298 of memory cells 299 (also referred to as “cell pillar structures”) vertically extending through each block structure 242 of the stack structure 289. The block structures 242 are separated from one another by slot structures 291. The vertical strings 298 may be positioned within regions (e.g., memory array regions) of the block structure 242 horizontally offset (e.g., in the X-direction) from the staircase structures 218 within the block structures 242. Intersections of the vertical strings 298 and the conductive structures 286 of the tiers 287 of the block structures 242 of stack structure 289 form strings of memory cells 299 vertically extending through each block structure 242 of the stack structure 289. For each string of memory cells 299, the memory cells 299 thereof may be coupled in series with one another. Within each block structure 242, the conductive structures 286 of some of the tiers 287 thereof may serve as access line structures (e.g., word line structures) for the strings of memory cells 299 within the horizontal area of the block structure 242. In some embodiments, within each block structure 242, the memory cells 299 formed at the intersections of the conductive structures 286 of some of the tiers 287 and the vertical strings 298 comprise so-called “MONOS” (metal-oxide-nitride-oxide-semiconductor) memory cells. In additional embodiments, the memory cells 299 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 299 comprise so-called “floating gate” memory cells including floating gates (e.g., metallic floating gates) as charge storage structures. The floating gates may horizontally intervene between central structures of the vertical strings 298 and the conductive structures 286 of the different tiers 287 of the stack structure 289.

The microelectronic device 205 may further include at least one source structure 201, access line routing structures 207, first select gates 209 (e.g., upper select gates, drain select gates (SGDs)), select line routing structures 211, one or more second select gates 213 (e.g., lower select gates, source select gate (SGSs)), and digit line structures 215. The digit line structures 215 may vertically overlie and be coupled to the vertical strings 298 (and, hence, the strings of memory cells 299). The source structure 201 may vertically underlie and be coupled to the vertical strings 298 (and, hence, the strings of memory cells 299). In addition, the conductive contact structures 288 may couple various features of the microelectronic device 205 to one another as shown (e.g., the select line routing structures 211 to the first select gates 209; the access line routing structures 207 to the conductive structures 286 of the tiers 287 of the block structures 242 of the stack structure 289). The conductive contact structures 288 may be substantially similar to the conductive contact structures 188.

The digit line structures 215 may be electrically coupled to the strings of vertical strings 298 through first conductive interconnect structures 217 (only some of which are illustrated in FIG. 2 for clarity and ease of understanding the description).

The microelectronic device 205 may also include a base structure 219 positioned vertically below the vertical strings 298 (and, hence, the strings of memory cells 299). The base structure 219 may include at least one control logic region including control logic devices configured to control various operations of other features (e.g., the strings of memory cells 299) of the microelectronic device 205. As a non-limiting example, the control logic region of the base structure 219 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base structure 219 may be coupled to the source structure 201, the access line routing structures 207, the select line routing structures 211, and the digit line structures 215. In some embodiments, the control logic region of the base structure 219 includes CMOS (complementary metal-oxide-semiconductor) circuitry. In such embodiments, the control logic region of the source structure 201 may be characterized as having a “CMOS under Array” (“CuA”) configuration.

Thus, in accordance with some embodiments of the disclosure, a memory device comprises a stack structure comprising tiers each comprising a conductive structure and an insulative structure vertically neighboring the conductive structure, staircase structures comprising steps comprising horizontal edges of the tiers, the steps individually defined by more than one of the tiers, a first conductive contact structure in contact with a vertically uppermost conductive structure of one of the steps, a second conductive structure in contact with a vertically uppermost conductive structure of the one of the steps, the second conductive structure farther from a horizontal center of the one of the steps in a first horizontal direction than the first conductive contact structure, and strings of memory cells vertically extending through portions of the stack structure neighboring the staircase structures in a second horizontal direction.

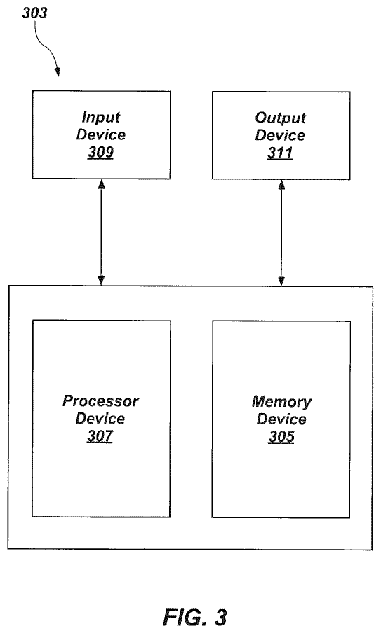

Microelectronic devices (e.g., the microelectronic device 205 including microelectronic device structures (e.g., the microelectronic device structures 100, 200)) of the disclosure may be included in embodiments of electronic systems of the disclosure. For example, FIG. 3 is a block diagram of an electronic system 303, in accordance with embodiments of the disclosure. The electronic system 303 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 303 includes at least one memory device 305. The memory device 305 may include, for example, an embodiment of a microelectronic device structure previously described herein (e.g., the microelectronic device structure 100, 200 previously described with reference to FIG. 1A through FIG. 1T, FIG. 2) or a microelectronic device (e.g., the microelectronic device 205) previously described with reference to FIG. 2.

The electronic system 303 may further include at least one electronic signal processor device 307 (often referred to as a “microprocessor”). The electronic signal processor device 307 may, optionally, include an embodiment of one or more of a microelectronic device and a microelectronic device structure previously described herein. The electronic system 303 may further include one or more input devices 309 for inputting information into the electronic system 303 by a user, such as, for example, a mouse or other pointing device, a keyboard, a touchpad, a button, or a control panel. The electronic system 303 may further include one or more output devices 311 for outputting information (e.g., visual or audio output) to a user such as, for example, a monitor, a display, a printer, an audio output jack, a speaker, etc. In some embodiments, the input device 309 and the output device 311 may comprise a single touchscreen device that can be used both to input information to the electronic system 303 and to output visual information to a user. The input device 309 and the output device 311 may communicate electrically with one or more of the memory device 305 and the electronic signal processor device 307.

Accordingly, in at least some embodiments, an electronic device comprises an input device, an output device, a processor device operably coupled to the input device and the output device, and a memory device operably coupled to the processor device and comprising at least one microelectronic device structure. The at least one microelectronic device structure comprises a stack structure comprising a vertically alternating sequence of levels of insulative structures and levels of conductive structures arranged in tiers, staircase structures having steps comprising horizontal edges of the tiers, each of the steps defined by horizontal edges of at least two of the tiers, conductive contact structures individually vertically extending from a vertically uppermost surface of the stack structure and contacting each of the levels of the conductive structure of each of the steps, and strings of memory cells horizontally neighboring the staircase structures and vertically extending through the stack structure.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
a stack structure comprising a vertically alternating sequence of conductive structures and insulative structures arranged in tiers;
a staircase structure comprising steps comprising horizontal edges of the tiers, each of the steps comprising multiple tiers; and
conductive contact structures vertically extending from a vertically upper surface of the stack structure to the conductive structures of the steps, the conductive structures defining each of the steps individually in contact with a conductive contact structure.

2. The microelectronic device of claim 1, wherein the each of the steps comprises three of the tiers.

3. The microelectronic device of claim 1, wherein the conductive structures contacting different conductive structures of the same step are electrically isolated from one another.

4. The microelectronic device of claim 1, wherein each of the conductive structures defining each of the steps is individually in electrical communication with two of the conductive contact structures.

5. The microelectronic device of claim 1, wherein a vertically uppermost surface of each of the steps comprises a surface of a vertically uppermost one of the insulative structures defining the step.

6. The microelectronic device of claim 1, wherein the conductive contact structures individually exhibit a greater dimension in a first horizontal direction than in a second horizontal direction.

7. The microelectronic device of claim 1, wherein, for each of the steps, the conductive contact structures vertically extend to the conductive structures outside of horizontal boundaries of a vertically uppermost level insulative structure defining the step.

8. The microelectronic device of claim 1, wherein conductive contact structures in contact with conductive levels defining one of the steps are located within horizontal boundaries of one another in a horizontal direction in which the steps of the staircase structure vertically ascend and descend.

9. The microelectronic device of claim 1, further comprising pillar structures each at least partially within horizontal boundaries defining one of the steps and at least partially outside of the horizontal boundaries defining the one of the steps, the pillar structures individually vertically extending through the stack structure.

10. A memory device, comprising:
a stack structure comprising tiers each comprising a conductive structure and an insulative structure vertically neighboring the conductive structure;
staircase structures comprising steps comprising horizontal edges of the tiers, the steps individually defined by more than one of the tiers;
a first conductive contact structure in contact with a vertically uppermost conductive structure of one of the steps;
a second conductive contact structure in contact with a vertically uppermost conductive structure of the one of the steps, the second conductive structure farther from a horizontal center of the one of the steps in a first horizontal direction than the first conductive contact structure; and
strings of memory cells vertically extending through portions of the stack structure neighboring the staircase structures in a second horizontal direction.

11. The memory device of claim 10, further comprising pillar structures vertically extending through the stack structure at the horizontal edges of the tiers.

12. The memory device of claim 11, wherein a first portion of each of the pillar structures is located outside of horizontal boundaries of the steps in the second horizontal direction and a second portion of the pillar structures are located within horizontal boundaries of the steps in the second horizontal direction.

13. The memory device of claim 10, further comprising a slot structure horizontally extending through the memory device in second first horizontal direction and separating the memory device into block structures each individually comprising some of the staircase structures.

14. The memory device of claim 13, wherein the first conductive contact structure is located closer to the slot structure than the second conductive contact structures.

15. The memory device of claim 10, wherein the first conductive contact structure and the second conductive contact structure individually comprise a contact connection region vertically between the one of the steps and a vertically uppermost surface of the stack structure.

16. The memory device of claim 15, wherein the first conductive contact structure and the second conductive contact structure individually horizontally extend in the first horizontal direction within the contact connection region.

17. An electronic system, comprising:
an input device;
an output device;
a processor device operably coupled to the input device and the output device; and
a memory device operably coupled to the processor device and comprising at least one microelectronic device, the at least one microelectronic device comprising:
a stack structure comprising a vertically alternating sequence of levels of insulative structures and levels of conductive structures arranged in tiers;
staircase structures having steps comprising horizontal edges of the tiers, each of the steps defined by horizontal edges of at least two of the tiers;
conductive contact structures individually vertically extending from a vertically uppermost surface of the stack structure and contacting each of the levels of the conductive structure of each of the steps; and
strings of memory cells horizontally neighboring the staircase structures and vertically extending through the stack structure.

18. The electronic system of claim 17, wherein the each of the steps are defined by horizontal edges of three of the tiers.

19. The electronic system of claim 17, wherein conductive contact structures in contact with portions of vertically uppermost conductive structures defining the steps are located farther from a center of the staircase structure than the conductive contact structures in contact with vertically lowermost conductive structures defining the steps.

20. The electronic system of claim 17, wherein each conductive level of each step is individually in contact with two of the conductive contact structures.
